(19) United States
(12) Patent Application Publication
(10) Pub. No.: US 2025/0301764 A1
(43) Pub. Date: Sep. 25, 2025

(54) SEMICONDUCTOR DEVICE AND METHODS OF FORMATION

(71) Applicant: Taiwan Semiconductor Manufacturing Company, Ltd,, Hsinchu (TW)

(72) Inventors: Yung-Chien HUANG, Kaohsiung City (TW); Tai-Wei HWANG, Kinmen County (TW); Hung-Chin CHUNG, Pingzhen City (TW); Da-Yuan LEE, Jhubei City (TW); Chien-Hao CHEN, Chuangwei Township (TW); Weng CHANG, Hsin-Chu (TW); Chi On CHUI, Hsinchu City (TW); Ming-Hsing TSAI, Chu-Pei City (TW)

(21) Appl. No.: 18/749,295

(22) Filed: Jun. 20, 2024

Related U.S. Application Data
(60) Provisional application No. 63/567,228, filed on Mar. 19, 2024.

(51) Int. Cl. H01L 21/8238; H01L 21/28; H01L 27/092; H01L 29/06; H01L 29/423; H01L 29/49; H01L 29/66; H01L 29/775; H01L 29/786

(52) U.S. Cl. CPC H10D 84/038; H01L 21/28088; H10D 30/014; H10D 30/031; H10D 30/43; H10D 30/6735; H10D 30/6739; H10D 30/6757; H10D 62/121; H10D 84/0167; H10D 84/0177; H10D 84/85

(57) ABSTRACT

Some implementations described herein provide semiconductor manufacturing techniques and associated semiconductor structures for forming p-type metal-oxide-semiconductor (PMOS) nanostructure transistors and n-type metal-oxide-semiconductor (NMOS) nanostructure transistors in a semiconductor device. The techniques described herein include forming respective (different) types of gate metals for a PMOS nanostructure transistor and keeping an intrinsic NMOS nanostructure transistor of the semiconductor device. A p-type gate metal may be formed around nanostructure channels for the PMOS nanostructure transistor. A self-assembled monolayer may then be formed on the surface of the p-type gate metal layer. During formation of an n-type gate metal around the nanostructure channels for the NMOS nanostructure transistor, the self-assembled monolayer on the p-type gate metal resists formation of the n-type gate metal on the p-type gate metal. This results in little-to-no n-type gate metal deposition on the p-type gate metal, which minimizes the p-type threshold voltage (PV) impact to the PMOS nanostructure transistor.

### CROSS-REFERENCE TO RELATED APPLICATION

This Patent Application claims priority to U.S. Provisional Patent Application No. 63/567,228, filed on Mar. 19, 2024, and entitled “SEMICONDUCTOR DEVICE AND METHODS OF FORMATION.” The disclosure of the prior Application is considered part of and is incorporated by reference into this Patent Application.

### BACKGROUND

As semiconductor device manufacturing advances and technology processing nodes decrease in size, transistors may become affected by short channel effects (SCEs) such as hot carrier degradation, barrier lowering, and quantum confinement, among other examples. In addition, as the gate length of a transistor is reduced for smaller technology nodes, source/drain (S/D) electron tunneling increases, which increases the off current for the transistor (the current that flows through the channel of the transistor when the transistor is in an off configuration). Silicon (Si)/silicon germanium (SiGe) nanostructure transistors such as nanowires, nanosheets, and gate-all-around (GAA) devices are potential candidates to overcome short channel effects at smaller technology nodes. Nanostructure transistors are efficient structures that may experience reduced SCEs and enhanced carrier mobility relative to other types of transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are diagrams of an example implementation of a fin definition process described herein.

FIG. 2 is a diagram of an example dummy gate structure formation process described herein.

FIG. 3 is a diagram of an example implementation of a source/drain recess formation process described herein.

FIGS. 4A and 4B are diagrams of an example implementation of an inner spacer formation process described herein.

FIG. 5 is a diagram of an example implementation of a source/drain region formation process described herein.

FIG. 6 is a diagram of an example implementation of an interlayer dielectric formation process described herein.

FIGS. 7A-7H are diagrams of an example implementation of a replacement gate process described herein.

FIG. 8 is a diagram of an example of elemental concentration in gate structures of a nanostructure transistor described herein.

FIG. 9 is a diagram of an example of elemental concentration in a gate structure of a nanostructure transistor described herein.

FIGS. 10A-10D are diagrams of example implementations of gate structures in a nanostructure transistor described herein.

FIGS. 11A and 11B are diagrams of an example implementation of forming work function metal layers of a gate structure of a nanostructure transistor described herein.

FIGS. 12 and 13 are flowcharts of example processes associated with forming a semiconductor device described herein.

FIGS. 14A-14I are diagrams of an example implementation of forming work function metal layers of a gate structure of a nanostructure transistor described herein.

FIG. 15 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A nanostructure transistor may include a gate structure that wraps around a plurality of nanostructure channels. The gate structure wrapping around the nanostructure channels increases control of the gate structure over a conductive channel in the nanostructure channels, increases drive current for the nanostructure transistor, and/or may reduce short channel effects (SCEs) for the nanostructure transistor, among other examples. In some cases, a semiconductor device may include p-type metal oxide semiconductor (PMOS) nanostructure transistors and n-type metal oxide semiconductor (NMOS) nanostructure transistors. Integrating PMOS nanostructure transistors and NMOS nanostructure transistors into the same semiconductor device enables complementary metal oxide semiconductor (CMOS) integrated circuits to be realized in the semiconductor device. CMOS integrated circuits have many use cases in the semiconductor industry, including microprocessors (e.g., central processing units (CPUs)), graphics processing units (GPUs)), memory devices, digital logic circuitry, image sensors (e.g., CMOS image sensors), and/or radio frequency (RF) circuitry, among other examples.

The threshold voltage (Vₜ) for a nanostructure transistor is the required gate voltage to selectively turn the nanostructure transistor on or off. If the threshold voltage for the nanostructure transistor is too low (meaning that the gate voltage for activating the nanostructure transistor is too low), the nanostructure transistor may experience a high amount of current leakage when the nanostructure transistor is off. Conversely, if the threshold voltage for the nanostructure transistor is too high, the power efficiency of the nanostructure transistor may be degraded because higher gate voltages are needed to operate the nanostructure transistor. For PMOS nanostructure transistors and NMOS nanostructure transistors, the types of metals that are used for the gate structures may directly impact the threshold voltages for the PMOS nanostructure transistors and the NMOS nanostructure transistors. Metals that tune the work function (φₘ) of a gate structure for optimal performance of a PMOS nanostructure transistor may result in a large band gap between the work function of a gate structure of an NMOS nanostructure transistor and the conduction band (E_{C}), resulting in a high threshold voltage (and low power efficiency) for the NMOS nanostructure transistor. Metals that tune the work function of a gate structure for optimal performance of an NMOS nanostructure transistor may result in a large band gap between the work function of a gate structure of a PMOS nanostructure transistor and the valance band (E_{V}), resulting in a high threshold voltage (and low power efficiency) for the PMOS nanostructure transistor.

Some implementations described herein provide semiconductor manufacturing techniques and associated semiconductor structures for forming PMOS nanostructure transistors and NMOS nanostructure transistors in a semiconductor device. The techniques described herein include forming respective (different) types of gate metals for a PMOS nanostructure transistor and keeping an intrinsic NMOS nanostructure transistor of the semiconductor device. A p-type gate metal may be formed around nanostructure channels for the PMOS nanostructure transistor. A self-assembled monolayer may then be formed on the surface of the p-type gate metal layer. During formation of an n-type gate metal around the nanostructure channels for the NMOS nanostructure transistor, the self-assembled monolayer on the p-type gate metal resists formation of the n-type gate metal on the p-type gate metal. This results in little-to-no n-type gate metal deposition on the p-type gate metal, which minimizes the p-type threshold voltage (PVₜ) impact to the PMOS nanostructure transistor. In this way, the techniques described herein enable the work functions of the NMOS nanostructure transistor and the PMOS nanostructure transistor to both be tuned for achieving desirable threshold voltages for the NMOS nanostructure transistor and the PMOS nanostructure transistor. This enables low current leakages to be achieved for the NMOS nanostructure transistor and the PMOS nanostructure transistor, and enables a high operating efficiency to be achieved for the NMOS nanostructure transistor and the PMOS nanostructure transistor.

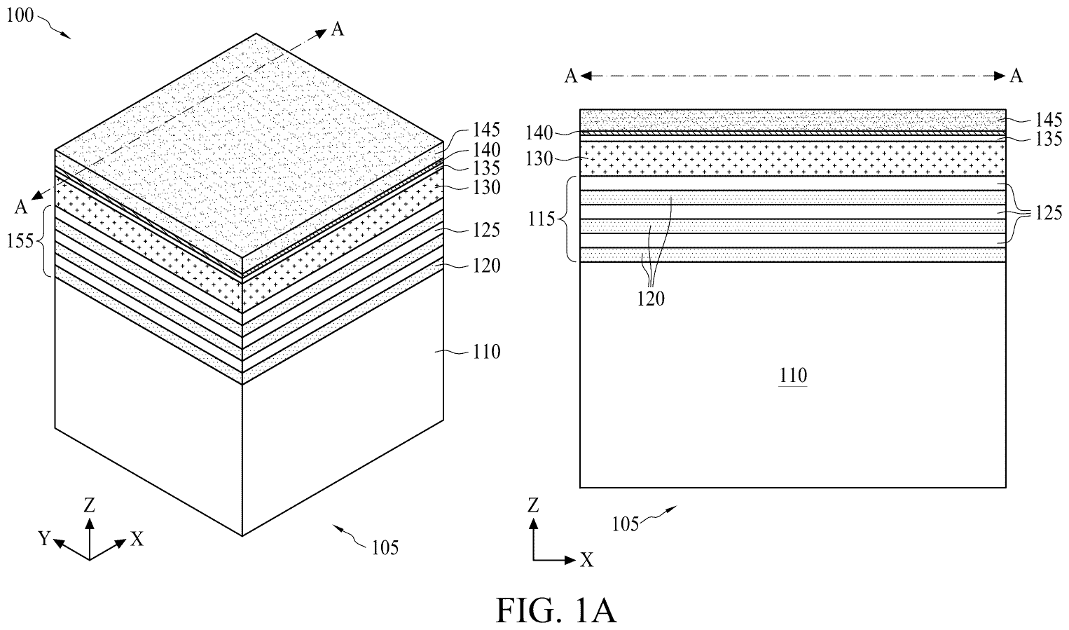

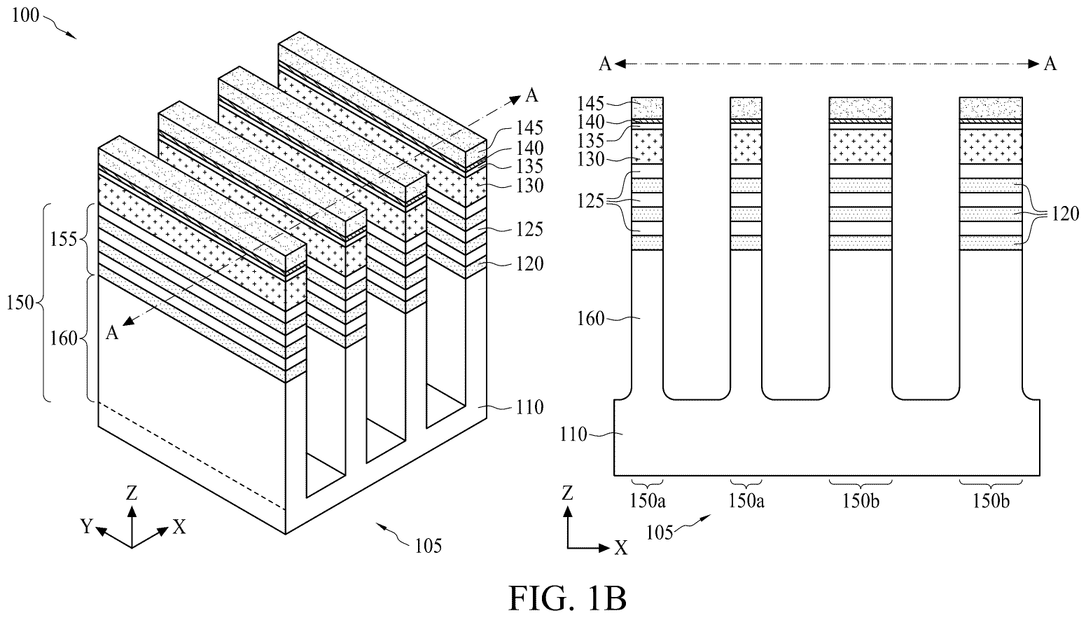

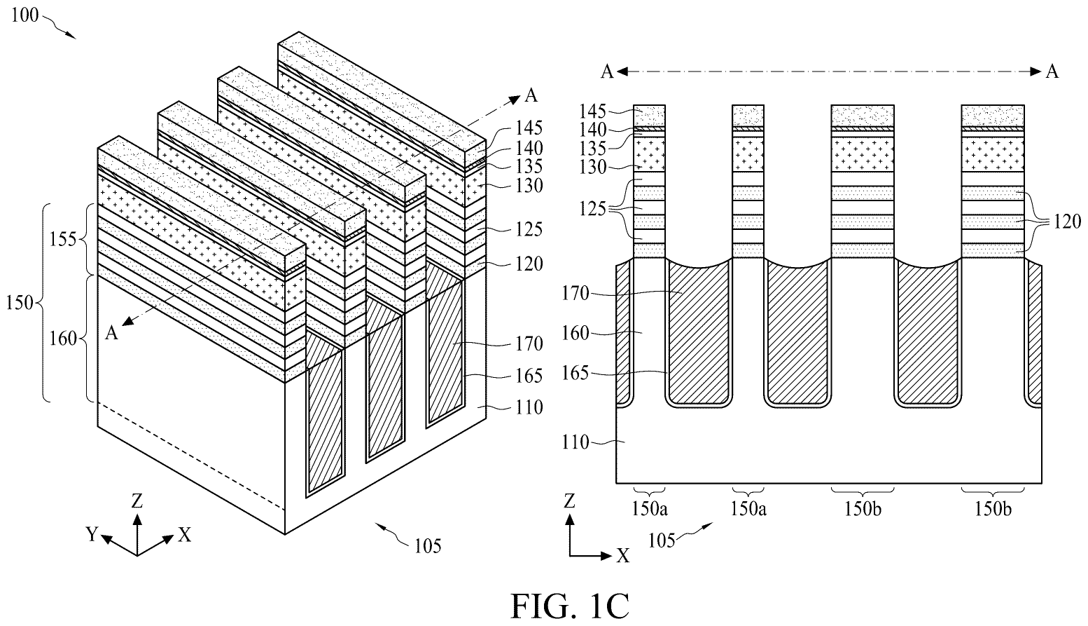

FIGS. 1A-1C are diagrams of an example implementation 100 of a fin definition process described herein. The example implementation 100 includes an example of forming fin structures and associated shallow trench isolation (STI) regions for a semiconductor device 105 described herein. The semiconductor device 105 may be manufactured to include one or more transistors. The one or more transistors may include nanostructure transistor(s) such as nanowire transistors, nanosheet transistors, gate-all-around (GAA) transistors, multi-bridge channel transistors, nanoribbon transistors, and/or other types of nanostructure transistors. The example implementation 100 includes an example of forming the fin structures and the associated STI regions for the transistors of the semiconductor device 105.

FIGS. 1A-1C each illustrate a perspective view of the semiconductor device 105 and a cross-sectional view along the line A-A in the perspective view. As shown in FIGS. 1A, processing of the semiconductor device 105 is performed in connection with a semiconductor substrate 110. The semiconductor substrate 110 includes a silicon (Si) substrate, a substrate formed of a material including silicon, a III-V compound semiconductor material substrate such as gallium arsenide (GaAs), a silicon on insulator (SOI) substrate, a germanium (Ge) substrate, a silicon germanium (SiGe) substrate, a silicon carbide (SiC) substrate, or another type of semiconductor substrate.

A layer stack 115 is formed on the semiconductor substrate 110. The layer stack 115 may be referred to as a superlattice. The layer stack 115 includes a plurality of alternating layers that are arranged in a direction (e.g., the z-direction) that is approximately perpendicular to the semiconductor substrate 110. For example, the layer stack 115 includes vertically alternating layers of sacrificial nanostructure layers 120 and nanostructure channel layers 125 above the semiconductor substrate 110. The quantity of the sacrificial nanostructure layers 120 and the quantity of the nanostructure channel layers 125 illustrated in FIG. 1A are examples, and other quantities of the sacrificial nanostructure layers 120 and the nanostructure channel layers 125 are within the scope of the present disclosure.

The sacrificial nanostructure layers 120 enable a vertical distance to be defined between adjacent nanostructure channels that are formed from the nanostructure channel layers 125, and serve as placeholder layers for subsequently-formed gate structures of the transistors of the semiconductor device 105 that are formed around the nanostructure channels. The sacrificial nanostructure layers 120 include a first material composition, and the nanostructure channel layers 125 include a second material composition. In some implementations, the first material composition and the second material composition are the same material composition. In some implementations, the first material composition and the second material composition are different material compositions. As an example, the sacrificial nanostructure layers 120 may include silicon germanium (SiGe) and the nanostructure channel layers 125 may include silicon (Si). This enables the sacrificial nanostructure layers 120 and/or the nanostructure channel layers 125 to be selectively etched (e.g., enables the sacrificial nanostructure layers 120 and not the nanostructure channel layers 125 to be etched, enables the nanostructure channel layers 125 and not the sacrificial nanostructure layers 120 to be etched) depending on the type of etchant that is used.

One or more types of deposition tools may be used to deposit and/or grow the alternating layers of the layer stack 115 to include nanostructures (e.g., nanosheets) on the semiconductor substrate 110. For example, a deposition tool may be used to grow the sacrificial nanostructure layers 120 and/or the nanostructure channel layers 125 by epitaxial growth, which may include epitaxy techniques such as a molecular beam epitaxy (MBE), metalorganic chemical vapor deposition (MOCVD) process, and/or another suitable epitaxy technique. Additionally and/or alternatively, the sacrificial nanostructure layers 120 and/or the nanostructure channel layers 125 may be deposited by chemical vapor deposition (CVD), physical vapor deposition (PVD), atomic layer deposition (ALD), and/or another suitable deposition technique.

One or more masking layers may be formed (e.g., using one or more deposition tools) on the layer stack 115. The masking layer(s) may include a hard mask (HM) layer 130, a capping layer 135, an oxide layer 140, and/or a nitride layer 145. Masking layer(s) may be used to perform a fin patterning operation to form fin structures in the semiconductor substrate 110.

As shown in FIG. 1B, the layer stack 115 and the semiconductor substrate 110 are etched to remove portions of the layer stack 115 and portions of the semiconductor substrate 110. This results in formation of fin structures 150 that extend above the semiconductor substrate 110. The fin structures 150 may extend in a y-direction in the semiconductor device 105 and may be arranged in an x-direction in the semiconductor device 105. A fin structure 150 includes a portion 155 of the layer stack 115 over and/or on a fin portion 160 above the semiconductor substrate 110. The fin structures 150 may be formed by patterning the one or more masking layers and etching the semiconductor substrate 110 based on a pattern formed in one or more of the masking layers. The one or more masking layers may be patterned using photolithography techniques, including double-patterning or multi-patterning techniques. An etch tool may be used to etch the semiconductor substrate 110 based on the pattern using a dry etch technique (e.g., reactive ion etching), a wet etch technique, and/or a combination thereof.

As further shown in FIG. 1B, some fin structures 150 may be formed to have different widths for different types of nanostructure transistors. As an example, a first subset of fin structures 150a may be formed for p-type nanostructure transistors (e.g., p-type metal oxide semiconductor (PMOS) nanostructure transistors), and a second subset of fin structures 150b may be formed for n-type nanostructure transistors (e.g., n-type metal oxide semiconductor (NMOS) nanostructure transistors). As another example, a first subset of fin structures 150a may be formed for nanostructure transistors that are configured to operate at lower voltages, and a second subset of fin structures 150b may be formed for nanostructure transistors that are configured to operate at higher voltages.

As shown in FIG. 1C, a liner 165 and STI regions 170 are formed between adjacent fin portions 160 of the fin structures 150. The liner 165 and the STI regions 170 may each include a dielectric material such as a silicon oxide (SiOₓ), a silicon nitride (SiₓN_{y}), a silicon oxynitride (SiON), fluoride-doped silicate glass (FSG), a low-k dielectric material, and/or another suitable insulating material.

A deposition tool may be used to conformally deposit the liner (e.g., using ALD or another conformal deposition technique), and may deposit a dielectric layer (e.g., using CVD, PVD, a ALD, and/or another suitable deposition technique) on the liner 165 such that the dielectric layer fully fills in the spaces between the fin structures 150 and extends above the tops of the fin structures 150. A planarization tool may then be used to perform a planarization or polishing operation (e.g., a chemical mechanical planarization (CMP) operation) to planarize the dielectric layer such that the top surface of the dielectric layer is approximately co-planar with the top of the nitride layer 145. The nitride layer 145 functions as a CMP stop layer in the planarization operation. An etch tool may be used to then etch the dielectric layer to form the STI regions 170 such that the top surfaces of the STI region 170 are approximately co-planar with or below the bottom-most sacrificial nanostructure layer 120.

As indicated above, FIGS. 1A-1C are provided as an example. Other examples may differ from what is described with regard to FIGS. 1A-1C.

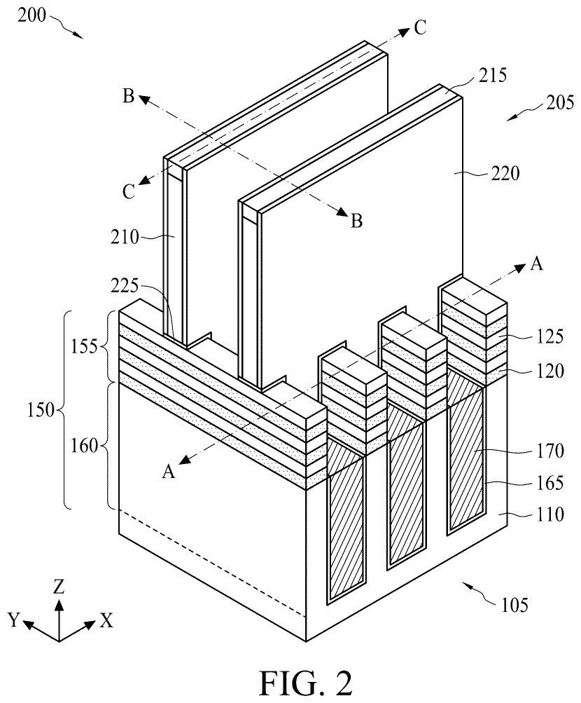

FIG. 2 is a diagram of an example implementation 200 of a dummy gate formation process described herein. The example implementation 200 includes an example of forming dummy gate structures 205 for nanostructure transistors of the semiconductor device 105. In some implementations, the operations described in connection with the example implementation 200 are performed after the processes described in connection with FIGS. 1A-1C.

FIG. 2 illustrates a perspective view of the semiconductor device 105 with the dummy gate structures 205 formed thereon. The dummy gate structures 205 (also referred to as dummy gate stacks or temporary gate structures) are formed over portions of the fin structures 150 and portions of the STI regions 170. The dummy gate structures 205 extend in the x-direction and are arranged in the y-direction such that the dummy gate structures 205 are approximately perpendicular to the fin structures 150. The dummy gate structures 205 are sacrificial structures that are to be replaced by replacement gate structures or replacement gate stacks at a subsequent processing stage for the semiconductor device 105. The dummy gate structures 205 may also be used to define source/drain (S/D) recesses in which source/drain regions of the nanostructure transistors are formed in the fin structures 150.

A dummy gate structure 205 may include a gate electrode layer 210, a hard mask layer 215 over and/or on the gate electrode layer 210, and spacer layers 220 on opposing sides of the gate electrode layer 210, and a gate dielectric layer 225 under the gate electrode layer 210. The gate electrode layer 210 includes polycrystalline silicon (polysilicon or PO) or another material. The hard mask layer 215 includes one or more layers such as an oxide layer (e.g., a pad oxide layer that may include silicon dioxide (SiO₂) or another material) and a nitride layer (e.g., a pad nitride layer that may include a silicon nitride such as Si₃N₄ or another material) formed over the oxide layer. The spacer layers 220 include a silicon oxycarbide (SiOC), a nitrogen free SiOC, or another suitable material. The gate dielectric layer 225 may include a silicon oxide (e.g., SiOₓ such as SiO₂), a silicon nitride (e.g., SiₓN_{y} such as Si₃N₄), a high dielectric constant (high-k) dielectric material (e.g., a dielectric material having a dielectric constant greater than approximately 3.9) and/or another suitable material.

The layers of the dummy gate structures 205 may be formed using various semiconductor processing techniques such as depositing the layers of the dummy gate structures 205, patterning the layers of the dummy gate structures 205 to define the dummy gate structures 205, and/or other semiconductor processing techniques.

FIG. 2 further illustrates reference cross-sections that are used in subsequent figures described herein. Cross-section A-A is in an x-z plane (referred to as a y-cut) across the fin structures 150 in the source/drain areas of the semiconductor device 105. Cross-section B-B is in a y-z plane (referred to as an x-cut) perpendicular to the cross-section A-A, and is across the dummy gate structures 205 and along an underlying fin structure 150. Cross-section C-C is in the x-z plane parallel to the cross-section A-A and perpendicular to the cross-section B-B, and is along a dummy gate structure 205. Subsequent figures refer to these reference cross-sections for clarity. In some figures, some reference numbers of components or features illustrated therein may be omitted to avoid obscuring other components or features for ease of depicting the figures.

As indicated above, FIG. 2 is provided as an example. Other examples may differ from what is described with regard to FIG. 2.

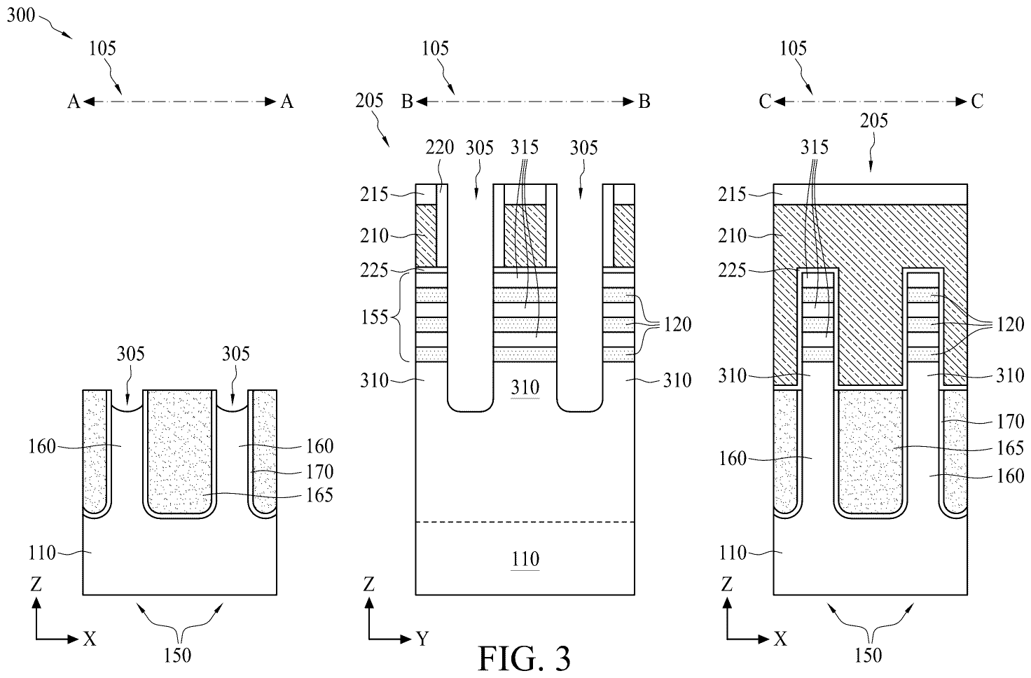

FIG. 3 is a diagrams of an example implementation 300 of a source/drain recess formation process described herein. The example implementation 300 includes an example of forming source/drain recesses 305 for source/drain regions of nanostructure transistors of the semiconductor device 105. FIG. 3 is illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 300 are performed after the processes described in connection with FIGS. 1A-2.

As shown in the cross-sectional plane A-A and cross-sectional plane B-B in FIG. 3, the source/drain recesses 305 are formed through portions 155 of a fin structure 150 in an etch operation. The source/drain recesses 305 are formed on opposing sides of a dummy gate structure 205. The etch operation may be performed using the etch tool and may be referred to a strained source/drain (SSD) etch operation. In some implementations, the etch operation includes the use of a plasma etch technique, a wet chemical etch technique, and/or another type of etch technique.

The source/drain recesses 305 also extend into a portion of the fin portion 160 of the fin structure 150. This results in formation of mesa regions 310 in the fin structure 150. The sidewalls of the portions of each source/drain recess 305 below the layer stack 115 correspond to sidewalls of mesa regions 310. A mesa region 310 (also referred to as pedestals) refers to a region of the fin portion 160 of the fin structure 150 on which nanostructure channels are defined from the nanostructure channel layers 125. The nanostructure channels 315 extend between adjacent source/drain recesses 305.

The nanostructure channels 315 include silicon-based nanostructures (e.g., nanosheets or nanowires, among other examples) that function as the semiconductive channels of the nanostructure transistors of the semiconductor device 105. In some implementations, the nanostructure channels 315 may include silicon germanium (SiGe) or another silicon-based material. The nanostructure channels 315 are arranged in a direction (e.g., the z-direction) that is approximately perpendicular to the semiconductor substrate 110. In other words, the nanostructure channels 315 are vertically arranged or stacked above the semiconductor substrate 110.

As indicated above, FIG. 3 is provided as an example. Other examples may differ from what is described with regard to FIG. 3.

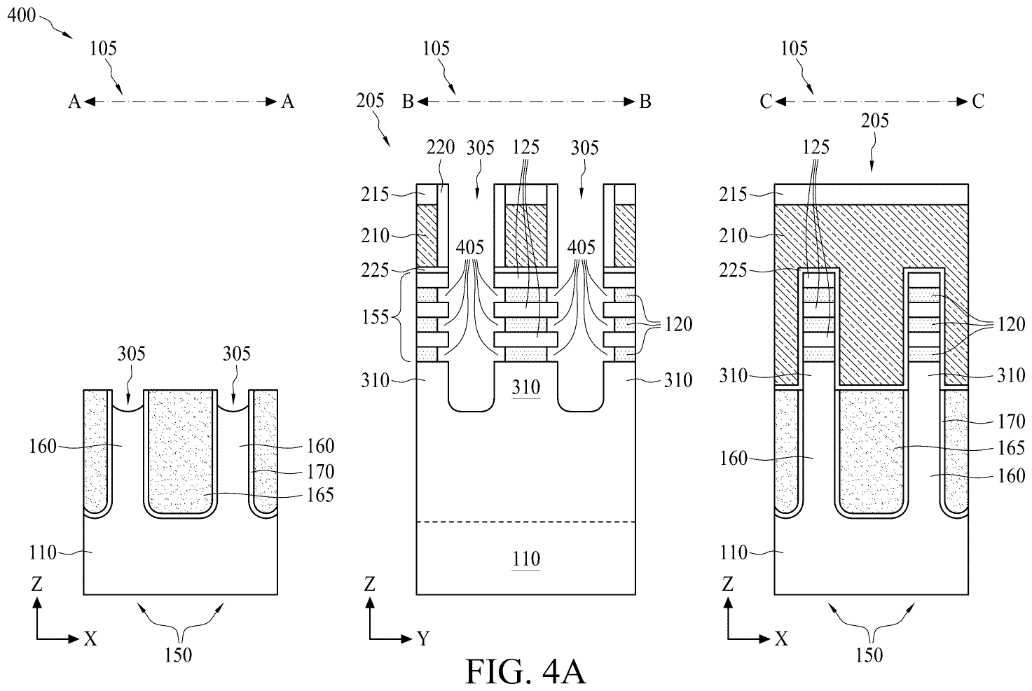

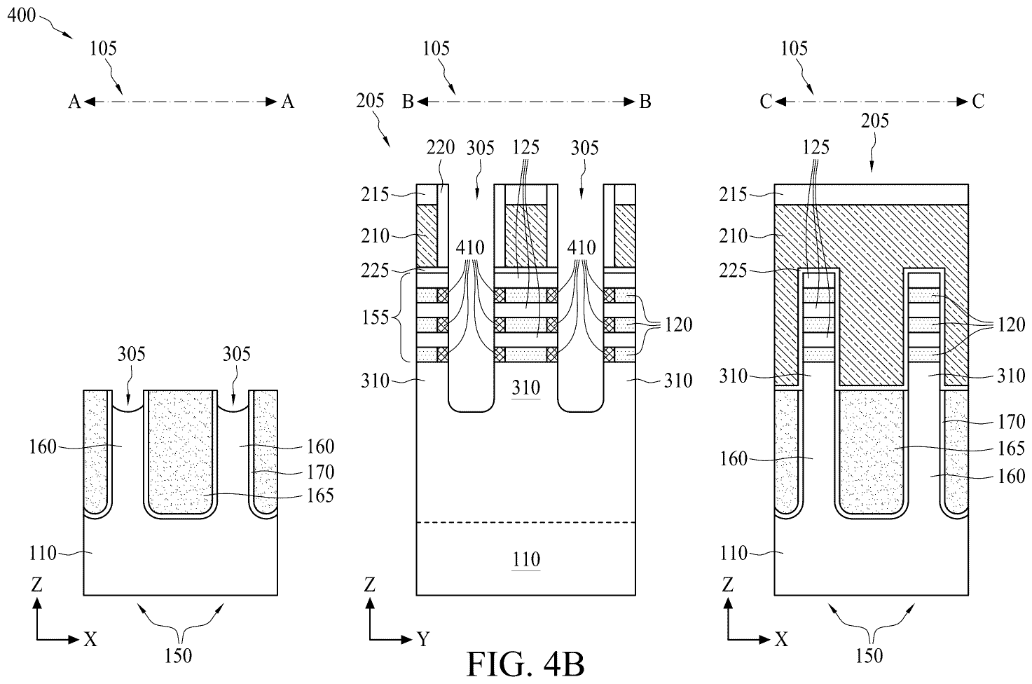

FIGS. 4A and 4B are diagrams of an example implementation 400 of an inner spacer formation process described herein. The example implementation 400 includes an example of forming inner spacers between ends of the nanostructure channels 315 that are exposed in the source/drain recesses 305. FIGS. 4A and 4B are each illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 400 are performed after the processes described in connection with FIGS. 1A-3.

As shown in the cross-sectional plane B-B in FIG. 4A, the ends of the sacrificial nanostructure layers 120 that are exposed in the source/drain recesses 305 are laterally etched (e.g., in the x-direction that is approximately parallel to a length of the sacrificial nanostructure layers 120) in an etch operation, thereby forming cavities 405 between the ends of the nanostructure channels 315 that are exposed in the source/drain recesses 305. In particular, an etch tool may be use to laterally etch the ends of the sacrificial nanostructure layers 120 under the dummy gate structures 205 through the source/drain recesses 305 to form the cavities 405 between ends of the nanostructure channels 315. The cavities 405 may be formed to an approximately curved shape, an approximately concave shape, an approximately triangular shape, an approximately square shape, or to another shape.

As shown in the cross-sectional plane A-A and in the cross-sectional plane B-B in FIG. 4B, inner spacers (InSP) 410 are formed in the cavities 405 between the ends of vertically adjacent nanostructure channels 315 in the source/drain recesses 305. The inner spacer 410 are included to reduce parasitic capacitance in the nanostructure transistors and to protect source/drain regions (that are subsequently formed in the source/drain recesses 305) from being etched in a nanosheet release operation to remove the sacrificial nanostructure layers 120 between the nanostructure channels 315. The inner spacers 410 include a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another dielectric material.

To form the inner spacers 410, a deposition tool may be used to deposit a layer of dielectric material in the cavities 405 and along the sidewalls and bottom surface of the source/drain recesses. A CVD technique, a PVD technique, and ALD technique, and/or another deposition technique may be used to deposit the layer of dielectric material. An etch tool is used to subsequently remove excess material of the layer of dielectric material from the source/drain recesses such that remaining portions correspond to the inner spacers 410 in the cavities 405. In some implementations, the etch operation may result in the surfaces of the inner spacers 410 facing the source/drain recesses 305 being curved or recessed. In some implementations, the surfaces of the inner spacers 410 facing the source/drain recesses 305 are approximately flat such that the surfaces of the inner spacers 410 and the surfaces of the ends of the nanostructure channels 315 are approximately even and flush.

As indicated above, FIGS. 4A and 4B are provided as an example. Other examples may differ from what is described with regard to FIGS. 4A and 4B.

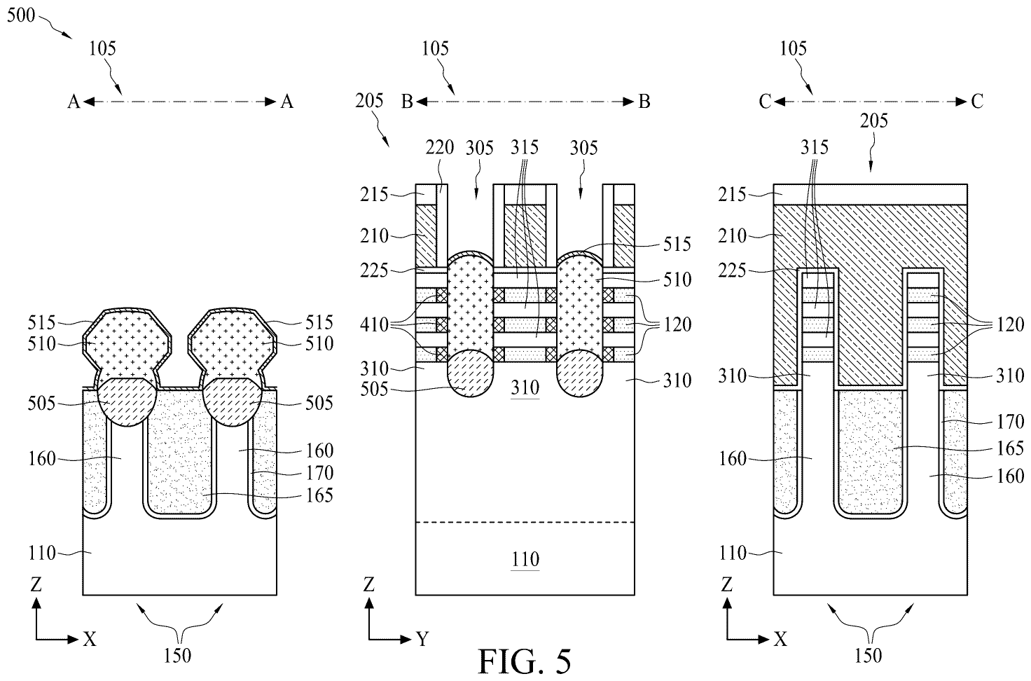

FIG. 5 is a diagram of an example implementation 500 of a source/drain region formation process described herein. The example implementation 500 includes an example of forming the source/drain regions of the nanostructure transistors of the semiconductor device 105. FIG. 5 is illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 500 are performed after the processes described in connection with FIGS. 1A-4B.

As shown in the cross-sectional plane A-A and the cross-sectional plane B-B in FIG. 5, the source/drain recesses 305 are filled with one or more layers to form the source/drain regions in the source/drain recesses 305. For example, a deposition tool may be used to deposit a buffer region 505 at the bottom of a he source/drain recess 305, and a deposition tool may deposit a source/drain region 510 on the buffer region 505 in the source/drain recess 305. In some implementations, a deposition tool is used to deposit a capping layer 515 on the source/drain regions 510 in the source/drain recess 305.

A buffer region 505 may include silicon (Si), silicon doped with boron (SiB) or another dopant, and/or another material. A buffer region 505 may be included between a source/drain region 510 and the mesa regions 310 adjacent to the buffer region 505 to reduce, minimize, and/or prevent dopant migration and/or current leakage from the source/drain region 510 into the adjacent mesa region 310, which might otherwise cause short channel effects in the semiconductor device 105. Accordingly, the buffer region 505 may increase the performance of the semiconductor device 105 and/or increase yield of the semiconductor device 105.

A source/drain region 510 may refer to a source or a drain, individually or collectively dependent upon the context. Source/drain regions 510 may be included on opposing sides of a dummy gate structure 205 such that the nanostructure channels 315 under the dummy gate structure 205 extend between, and are electrically coupled with, source/drain regions 510. The source/drain regions 510 each include silicon (Si) with one or more dopants, such as a p-type material (e.g., boron (B) or germanium (Ge), among other examples), an n-type material (e.g., phosphorous (P) or arsenic (As), among other examples), and/or another type of dopant. Accordingly, the semiconductor device 105 may include p-type metal-oxide semiconductor (PMOS) nanostructure transistors that include p-type source/drain regions 510, n-type metal-oxide semiconductor (NMOS) nanostructure transistors that include n-type source/drain regions 510, and/or other types of nanostructure transistors.

One or more layers of a source/drain region 510 may be epitaxially grown, deposited (e.g., using CVD, PVD, ALD), and/or may be formed using one or more other deposition techniques. For example, a deposition tool may epitaxially grow a first layer of a source/drain region 510 (referred to as an L1) over an associated buffer region 505 (which may be referred to as an L0), and may epitaxially grow a second layer of the source/drain region 510 (referred to as an L2, an L2-1, and/or an L2-2) over the first layer. The first layer may include a lightly doped silicon (e.g., doped with boron (B), phosphorous (P), and/or another dopant), and may be included as shielding layer to reduce short channel effects in the semiconductor device 105 and to reduce dopant extrusion or migration into the nanostructure channels 315. The second layer may include a highly doped silicon or highly doped silicon germanium. The second layer may be included to provide a compressive stress in the source/drain regions 510 to reduce boron loss.

A capping layer 515 may include silicon, silicon germanium, doped silicon, doped silicon germanium, and/or another material. The capping layer 515 may be included to reduce dopant diffusion and to protect an underlying source/drain regions 510 in semiconductor processing operations for the semiconductor device 105 prior to contact formation. Moreover, the capping layer 515 may contribute to metal-semiconductor (e.g., silicide) alloy formation.

As indicated above, FIG. 5 is provided as an example. Other examples may differ from what is described with regard to FIG. 5.

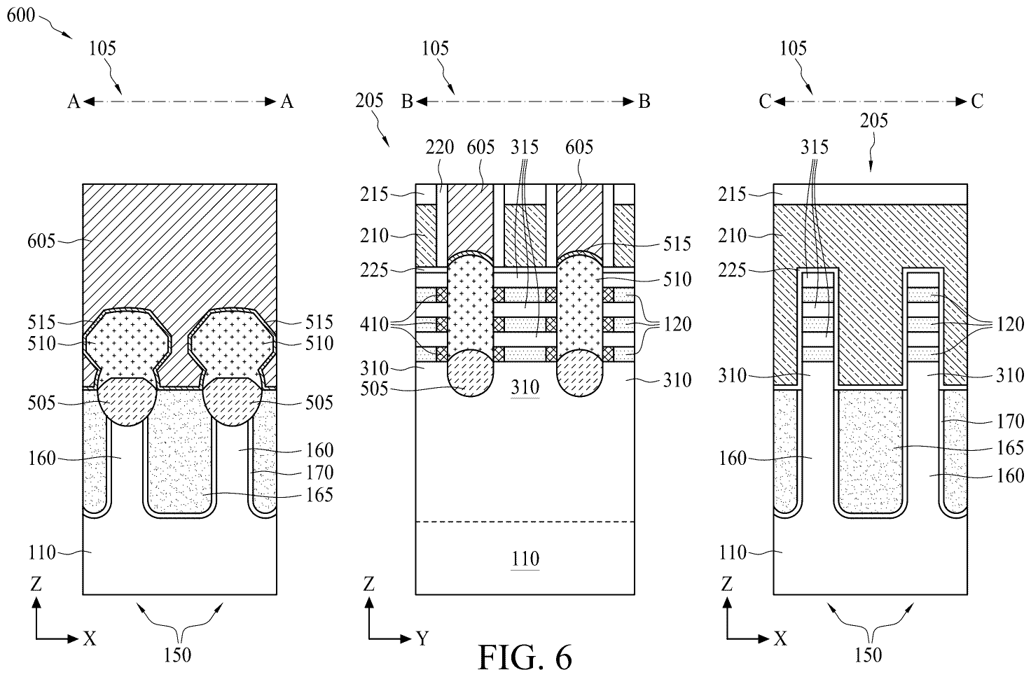

FIG. 6 is a diagram of an example implementation 600 of an interlayer dielectric (ILD) formation process described herein. FIG. 6 is illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 600 are performed after the processes described in connection with FIGS. 1A-5.

As shown in the cross-sectional plane A-A and the cross-sectional plane B-B in FIG. 6, a dielectric layer 605 is formed over the source/drain regions 510. The dielectric layer 605 (which may be referred to as an ILD layer) fills in areas between the dummy gate structures 205. The dielectric layer 605 is formed to reduce the likelihood of and/or prevent damage to the source/drain regions 510 during a replacement gate process to replace the dummy gate structures 205. The dielectric layer 605 may be referred to as an ILD zero (ILD0) layer or another ILD layer.

In some implementations, a contact etch stop layer (CESL) is conformally deposited (e.g., by a deposition tool) over the source/drain regions 510 prior to formation of the dielectric layer 605. Alternatively, the capping layer 515 may a CESL. The dielectric layer 605 is then formed on the CESL. The CESL may provide a mechanism to stop an etch process when forming contacts or vias for the source/drain regions 510. The CESL may be formed of a dielectric material having a different etch selectivity from adjacent layers or components. The CESL may include or may be a nitrogen containing material, a silicon containing material, and/or a carbon containing material. Furthermore, the CESL may include or may be silicon nitride (SiₓN_{y}), silicon carbon nitride (SiCN), carbon nitride (CN), silicon oxynitride (SiON), silicon carbon oxide (SiCO), or a combination thereof, among other examples. The CESL may be deposited using a deposition process, such as ALD, CVD, or another deposition technique.

As indicated above, FIG. 6 is provided as an example. Other examples may differ from what is described with regard to FIG. 6.

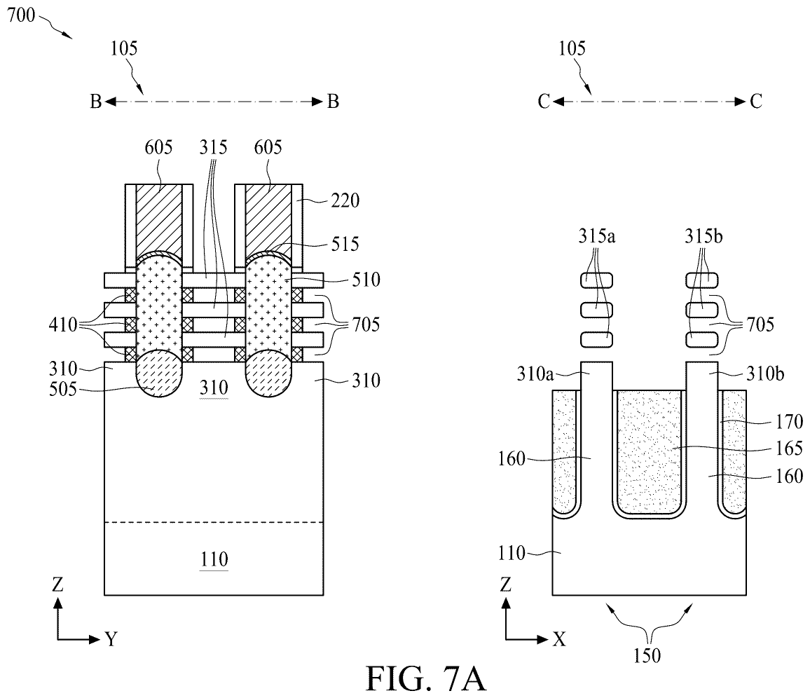

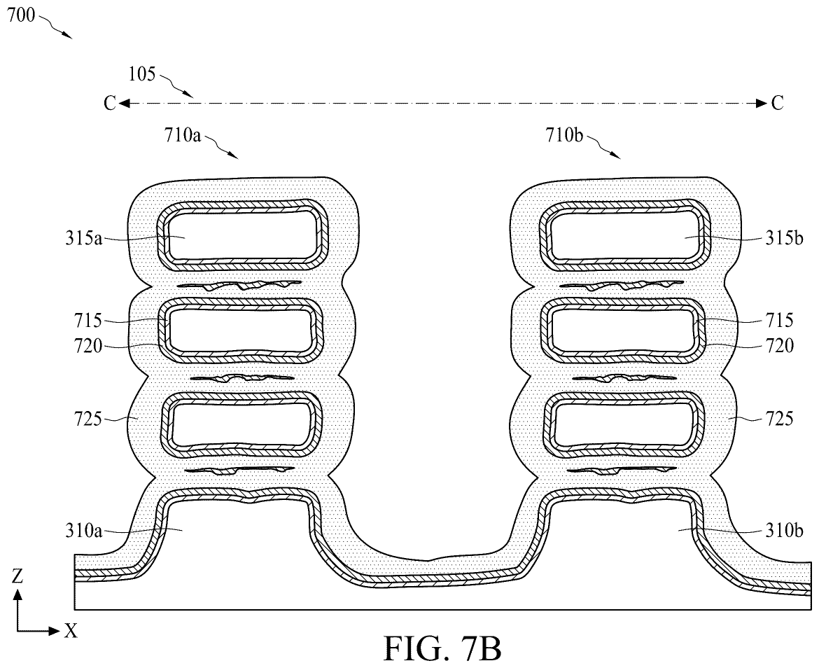

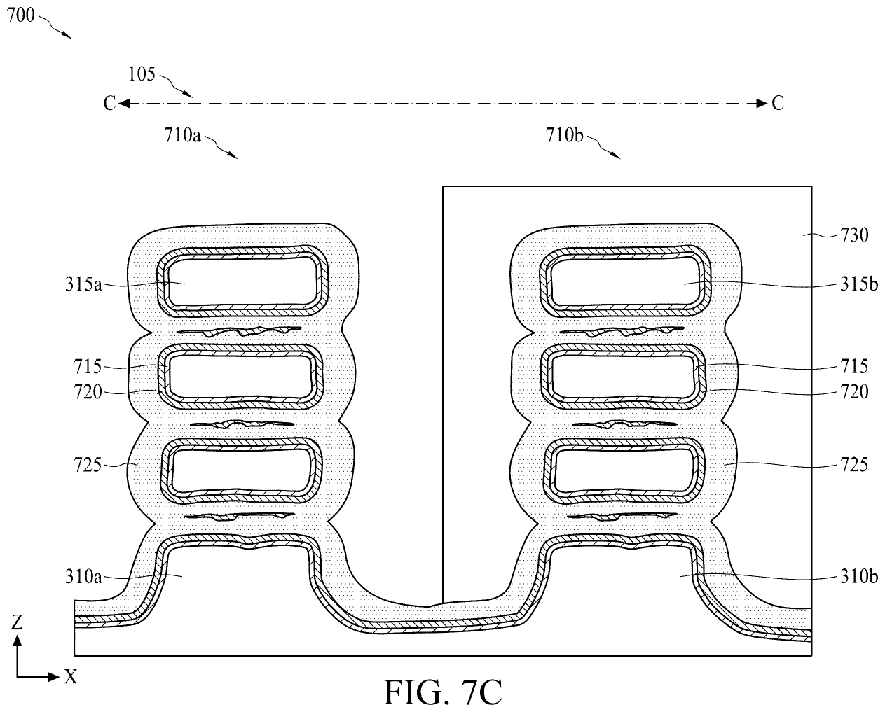

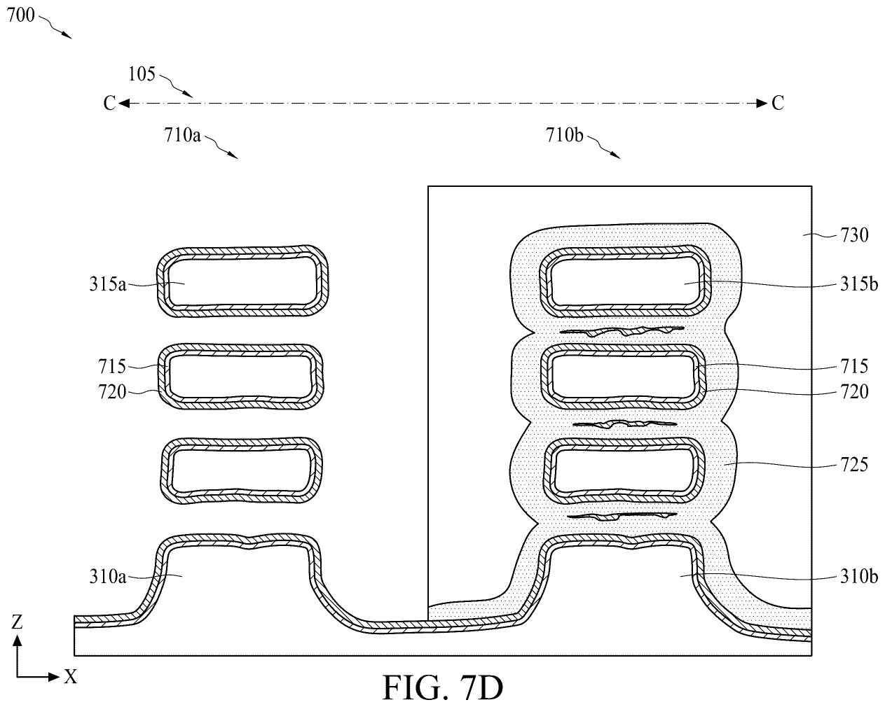

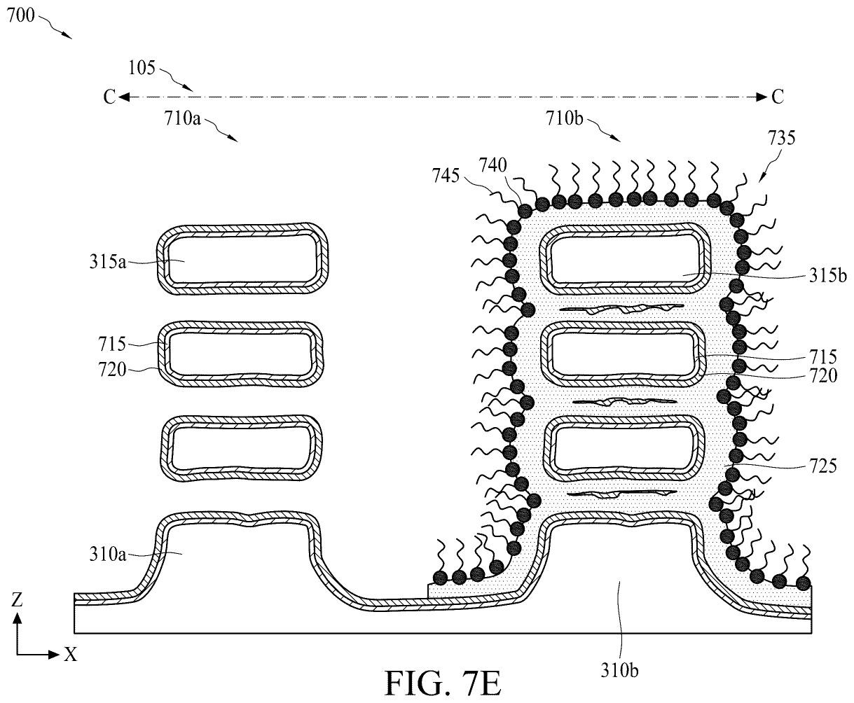

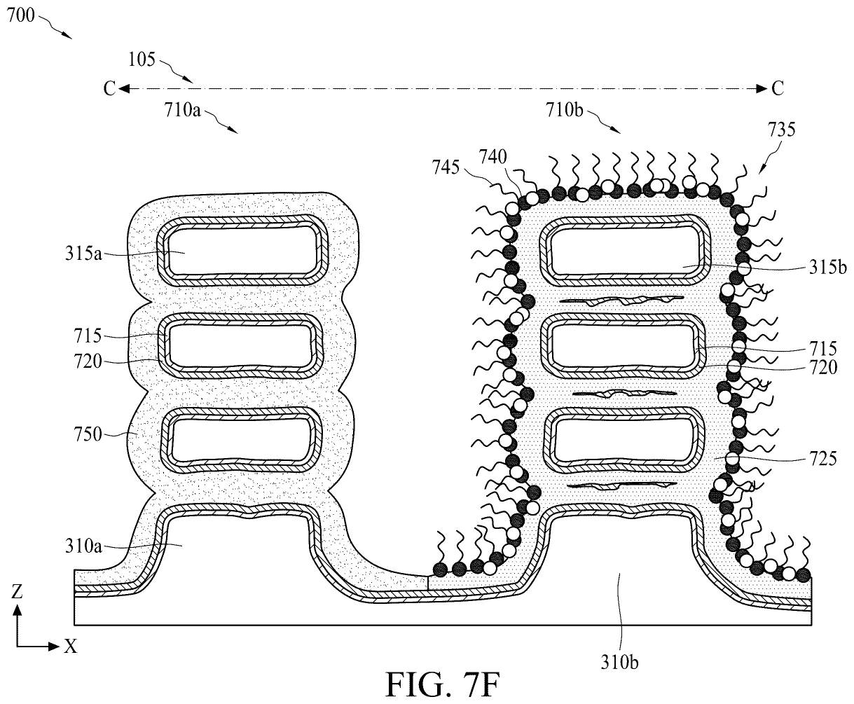

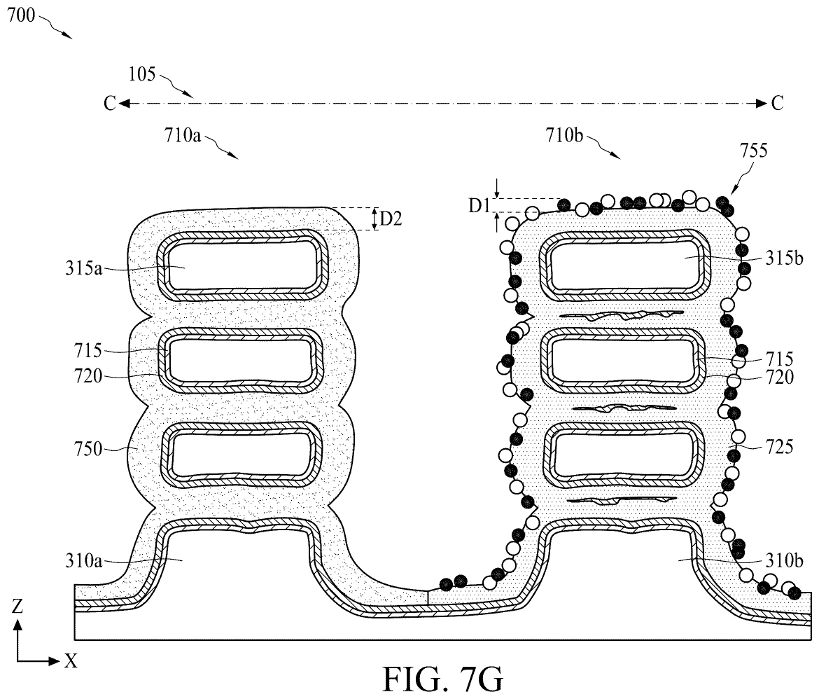

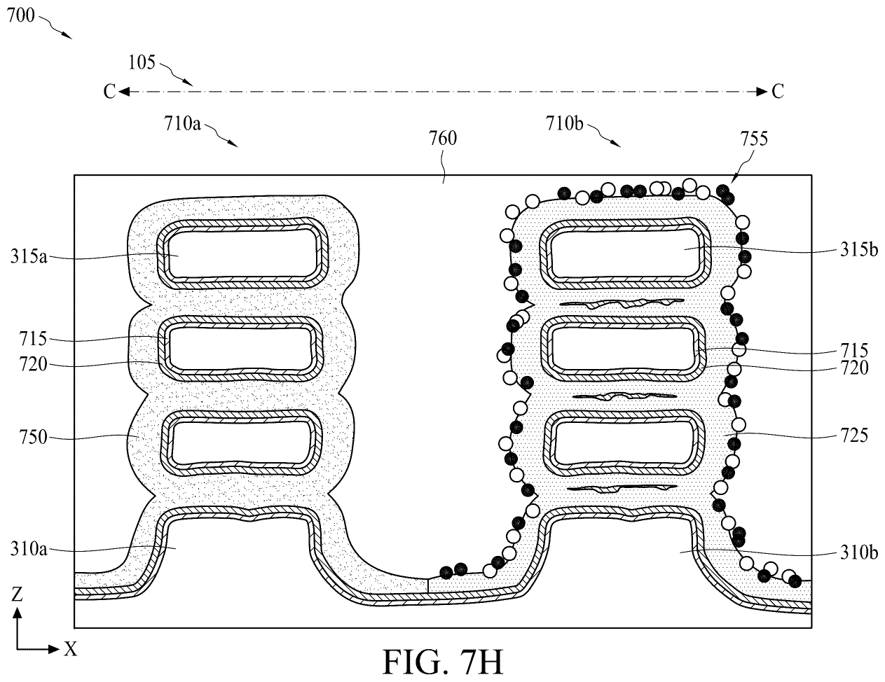

FIGS. 7A-7H are diagrams of an example implementation 700 of a replacement gate (RPG) process described herein. The example implementation 700 includes an example of a replacement gate process for replacing the dummy gate structures 205 with high-k/metal gate structures (e.g., the replacement gate structures) for the nanostructure transistors of the semiconductor device 105. FIGS. 7A-7H are each illustrated from one or more perspectives illustrated in FIG. 2, such as the perspective of the cross-sectional plane B-B in FIG. 2 and/or the perspective of the cross-sectional plane C-C in FIG. 2. In some implementations, the operations described in connection with the example implementation 700 are performed after the operations described in connection with FIGS. 1A-6.

As shown in the cross-sectional plane B-B and the cross-sectional plane C-C in FIG. 7A, the replacement gate process includes a dummy gate removal operation. The dummy gate removal operation includes removing the dummy gate structures 205 from the semiconductor device 105. The removal of the dummy gate structures 205 leaves behind openings (or recesses) between the dielectric layer 605, and provides access to the underlying sacrificial nanostructure layers 120. The dummy gate structures 205 may be removed in one or more etch operations. Such etch operations may include a plasma etch technique, a wet chemical etch technique, and/or another type of etch technique.

The removal of the dummy gate structures 205 exposes a mesa region 310a and a stack of nanostructure channels 315a that are arranged above the mesa region 310a in the z-direction in the semiconductor device 105. The removal of the dummy gate structures 205 also exposes a mesa region 310b and a stack of nanostructure channels 315b that are arranged above the mesa region 310b in the z-direction in the semiconductor device 105. The nanostructure channels 315a and the nanostructure channels 315b extend in the y-direction in the semiconductor device 105. The nanostructure channels 315a and the nanostructure channels 315b may be arranged in the x-direction in the semiconductor device 105 such that the nanostructure channels 315a and the nanostructure channels 315b are side-by-side or laterally adjacent in the semiconductor device 105.

The mesa region 310a and the nanostructure channels 315a may be exposed in preparation for forming an n-type gate structure, of an NMOS nanostructure transistor of the semiconductor device 105, around the nanostructure channels 315a. The mesa region 310b and the nanostructure channels 315b may be exposed in preparation for forming a p-type gate structure, of a PMOS nanostructure transistor of the semiconductor device 105, around the nanostructure channels 315b.

In some implementations, a z-direction thickness of a nanostructure channel 315a is included in a range of approximately 3 nanometers to approximately 10 nanometers. However, other values and ranges for the z-direction thickness of the nanostructure channels 315a are within the scope of the present disclosure. In some implementations, a z-direction thickness of a nanostructure channel 315b is included in a range of approximately 3 nanometers to approximately 10 nanometers. However, other values and ranges for the z-direction thickness of the nanostructure channels 315b are within the scope of the present disclosure.

In some implementations, a z-direction distance between vertically adjacent nanostructure channels 315a (e.g., channel-to-channel spacing) is included in a range of approximately 3 nanometers to approximately 10 nanometers. However, other values and ranges for the z-direction spacing between the nanostructure channels 315a are within the scope of the present disclosure. In some implementations, a z-direction distance between vertically adjacent nanostructure channels 315b (e.g., channel-to-channel spacing) is included in a range of approximately 3 nanometers to approximately 10 nanometers. However, other values and ranges for the z-direction spacing between the nanostructure channels 315b are within the scope of the present disclosure.

As further shown FIG. 7A, the replacement gate process includes a nanostructure release operation (e.g., an SiGe release operation). The nanostructure release operation is performed to remove the sacrificial nanostructure layers 120 (e.g., the silicon germanium layers). This results in openings 705 between the nanostructure channels 315a (e.g., the areas around the nanostructure channels 315a) and openings 705 between the nanostructure channels 315b (e.g., the areas around the nanostructure channels 315b). The sacrificial nanostructure layers 120 may be removed through the spaces that were previously occupied by the dummy gate structures 205. The nanostructure release operation may include the use of an etch tool to perform an etch operation to remove the sacrificial nanostructure layers 120 based on a difference in etch selectivity between the material of the sacrificial nanostructure layers 120 and the material of the nanostructure channels 315a and 315b, and between the material of the sacrificial nanostructure layers 120 and the material of the inner spacers 410. The inner spacers 410 may function as etch stop layers in the etch operation to protect the source/drain regions 510 from being etched.

As shown in FIG. 7B, an interfacial layer 715 may be formed around the nanostructure channels 315a and 315b. The interfacial layer 715 may be conformally deposited (e.g., using an ALD technique, a CVD technique, and/or another suitable conformal deposition technique) such that the interfacial layer 715 is deposited as a conformal thin film. The interfacial layer 715 may include silicon dioxide (SiO₂) and/or another suitable dielectric material that may be used to tune an interface between a gate dielectric layer 720 and the nanostructure channels 315a and 315b. In some implementations, the interfacial layer 715 may have a thickness that is included in a range of approximately 5 angstroms to approximately 25 angstroms. However, other values and ranges for the thickness of the interfacial layer 715 are within the scope of the present disclosure.

As further shown in FIG. 7B, a gate dielectric layer 720 is formed around the nanostructure channels 315a and 315b. The gate dielectric layer 720 may be conformally deposited (e.g., using an ALD technique, a CVD technique, and/or another suitable conformal deposition technique) such that the gate dielectric layer 720 is deposited as a conformal thin film.

The gate dielectric layer 720 may include one or more high-k materials (e.g., dielectric materials having a dielectric constant greater than silicon dioxide (SiO₂—dielectric constant of approximately 3.9). Examples of such high-k materials include lanthanum oxide (LaₓO_{y} such as La₂O₃), hafnium oxide (HfOₓ such as HfO₂), zirconium oxide (ZrOₓ such as ZrO₂), and/or aluminum oxide (AlₓO_{y} such as Al₂O₃), among other examples of high-k dielectric materials. Additionally and/or alternatively, silicon dioxide (SiO₂) and/or another dielectric material may be used instead of a high-k dielectric material.

In some implementations, the gate dielectric layer 720 is formed as a multiple-layer thin film that includes two or more layers of high-k dielectric material. For example, the gate dielectric layer 720 may include a first layer that includes hafnium oxide (HfOₓsuch as HfO2), and a second layer on the first layer, where the second layer includes zirconium oxide (ZrOₓsuch as ZrO₂). Other combinations of high-k dielectric layers for the gate dielectric layer 720 are within the scope of the present disclosure.

In some implementations, the gate dielectric layer 720 may have a thickness that is included in a range of approximately 5 angstroms to approximately 30 angstroms. However, other values and ranges for the thickness of the gate dielectric layer 720 are within the scope of the present disclosure.

As further shown in FIG. 7B, a p-type metal layer 725 is formed on the gate dielectric layer 720. In some implementations, an adhesion liner is first formed on the gate dielectric layer 720, and the p-type metal layer 725 is formed on the adhesion liner. The p-type metal layer 725 is formed on the exposed portions of the mesa regions 310a and 310b, and on the nanostructure channels 315a and 315b such that the p-type metal layer 725 wraps around the nanostructure channels 315a and 315b.

In some embodiments, the p-type metal layer 725 wraps around the nanostructure channels 315a and 315b such that the p-type metal layer 725 is merged between vertically adjacent pairs of the nanostructure channels 315a, and such that the p-type metal layer 725 is merged between vertically adjacent pairs of the nanostructure channels 315b. In some embodiments, the p-type metal layer 725 wraps around the nanostructure channels 315a and 315b, and is not merged between vertically adjacent pairs of the nanostructure channels 315a and/or is not merged between vertically adjacent pairs of the nanostructure channels 315b. In these implementations, seams may occur in the portions of the p-type metal layer 725 between vertically adjacent pairs of the nanostructure channels 315a and/or may occur in portions of the p-type metal layer 725 between vertically adjacent pairs of the nanostructure channels 315b.

Since the p-type gate structure 710b includes a metal gate structure, work function tuning for the p-type gate structure 710b may be performed by including one or more work function tuning metals in p-type gate structure 710b, unlike polysilicon gate structures for which a work function may be tuned by doping the polysilicon material with p-type dopants and/or n-type dopants. The p-type metal layer 725 may be included as a p-type work function metal in the p-type gate structure 710b to tune the work function of the p-type gate structure 710b. The p-type metal layer 725 may include one or more p-type metals, such as tungsten (W), cobalt (Co), titanium nitride (TiN), tungsten nitride (WN), and/or another metal having a work function that is greater than approximately 4.7 electron volts (eV), among other examples. The p-type metal layer 725 may be included to tune the work function of a PMOS nanostructure transistor such that the work function is adjusted close to the valance band of the material of the nanostructure channels 315b. This enables a relatively low threshold voltage to be achieved for the PMOS nanostructure transistor while enabling a relatively low current leakage to be achieved for the PMOS nanostructure transistor.

A deposition tool may be used to deposit the p-type metal layer 725 using a PVD technique, an ALD technique, a CVD technique, an oxidation technique, and/or another suitable deposition technique. The p-type metal layer 725 may be deposited in one or more deposition operations. In some implementations, the p-type metal layer 725 is formed to a thickness that is included in a range of approximately 0.1 angstrom to approximately 50 angstroms. However, other value and ranges for the thickness of the p-type metal layer 725 are within the scope of the present disclosure.

As indicated above, the p-type metal layer 725 is formed around the nanostructure channels 315a and 315b. This is due to the p-type metal layer 725 being formed without the use of a masking layer around the nanostructure channels 315a. If the p-type metal layer 725 were to remain around the nanostructure channels 315a, the p-type metal layer 725 might otherwise result in the work function for the n-type gate structure 710a being too far away from the conduction band of the material of the nanostructure channels 315a. Accordingly, and as shown in FIGS. 7C and 7D, the p-type metal layer 725 is removed from the nanostructure channels 315a after formation of the p-type metal layer 725.

As shown in FIG. 7C, a photoresist layer 730 may be formed over the semiconductor device 105. The photoresist layer 730 may be formed on the p-type metal layer 725 that is on the mesa region 310a, the mesa region 310b, the nanostructure channels 315a, and the nanostructure channels 315b. A deposition tool may be used to deposit the photoresist layer 730 using a spin coating technique and/or another deposition technique.

As further shown in FIG. 7C, a pattern is formed in the photoresist layer 730. The n-type gate structure 710a is exposed through the pattern in the photoresist layer 730. This enables the photoresist layer 730 to be used to remove the p-type metal layer 725 from the mesa region 310a and the nanostructure channels 315a, without removing the p-type metal layer 725 from the mesa region 310b and the nanostructure channels 315b. An exposure tool may be used to expose the photoresist layer 730 to a radiation source to pattern the photoresist layer 730. A developer tool may be used to develop and remove portions of the photoresist layer 730 that are on the mesa region 310a and the nanostructure channels 315a.

As shown in FIG. 7D, the portions of the p-type metal layer 725 exposed through the pattern in the photoresist layer 730 are removed from the mesa region 310a and from the nanostructure channels 315a. The photoresist layer 730 over the p-type gate structure 710b protects the portions of the p-type metal layer 725 from being removed from the mesa region 310b and from the nanostructure channels 315b. An etch tool may be used to etch the p-type metal layer 725 based on the pattern in the photoresist layer 730 to remove the portions of the p-type metal layer 725 from the mesa region 310a and from the nanostructure channels 315a. In some implementations, the etch operation includes a plasma etch operation, a wet chemical etch operation, and/or another type of etch operation.

Subsequently, a photoresist removal tool may be used to remove the remaining portions of the photoresist layer 730. The remaining portions of the photoresist layer 730 may be removed using a chemical stripper, plasma ashing, and/or another technique. Removal of the remaining portions of the photoresist layer 730 exposes the p-type metal layer 725 that is on the mesa region 310b and on the nanostructure channels 315b.

As shown in FIG. 7E, a self-assembled monolayer film 735 is formed on the p-type metal layer 725 of the p-type gate structure 710b. In other words, the self-assembled monolayer film 735 is formed on the p-type metal layer 725 that wraps around the nanostructure channels 315b and that is included on the mesa region 310b.

The self-assembled monolayer film 735 includes a “monolayer” film in that the self-assembled monolayer film 735 may have a single-molecule thickness (e.g., a thickness corresponding to a one-molecule thick layer of a material of the self-assembled monolayer film 735). The self-assembled monolayer film 735 is formed on the p-type metal layer 725 to block or inhibit formation of an n-type metal layer on the p-type metal layer 725. The n-type metal layer is to be subsequently formed on the nanostructure channels 315a for the n-type gate structure 710a for tuning the work function of the n-type gate structure 710a. The self-assembled monolayer film 735 minimizes or reduces the impact of the n-type metal layer on the work function of the p-type gate structure 710b.

The self-assembled monolayer film 735 includes one or more materials that enable the self-assembled monolayer film 735 to be selectively deposited on the p-type metal layer 725 with minimal to no deposition of the self-assembled monolayer film 735 on the gate dielectric layer 720 of the n-type gate structure 710a. For example, the self-assembled monolayer film 735 may be formed of a material that includes an anchoring group 740 that promotes adsorption of the material of the self-assembled monolayer film 735 on the p-type metal layer 725, and that resists adsorption onto the high-k dielectric material of the gate dielectric layer 720. In some implementations, the adsorption selectivity of the anchoring group 740 of the self-assembled monolayer film 735 may be included in a range of 20:1 (e.g., 20:1 adsorption onto the p-type metal layer 725 to adsorption onto the high-k dielectric material of the gate dielectric layer 720) to approximately 70:1, to achieve sufficient deposition selectivity for the self-assembled monolayer film 735. Examples of such materials include materials having an anchoring group 740 including an amino group (—NH₂ group), a thiol group (—SH group), a carboxyl group (—COOH group), a carbonyl group (—COH group), a trichlorosilane (—SiCl₃ group), and/or a phosphonate (—P group), among other examples. In some implementations, the anchoring group 740 includes nitrogen ligands (N-ligands), sulfur ligands (S-ligands), silicon ligands (Si-ligands), phosphorous ligands (P-ligands), and/or another type of ligands.

The self-assembled monolayer film 735 includes one or more materials that enable the self-assembled monolayer film 735 to block or inhibit precursors of the n-type metal layer of the n-type gate structure 710a from being adsorbed onto the p-type metal layer 725 of the p-type gate structure 710b. For example, the self-assembled monolayer film 735 may be formed of a material that includes a side chain group 745 that includes a hydrocarbon group such as an aryl group hydrocarbon chain, among other examples.

In some implementations, self-assembled monolayer film 735 is formed by depositing a solution that contains material of the self-assembled monolayer film 735 onto the surface of the p-type metal layer 725 using a spin-coating technique. In some implementations, a pre-cleaning operation uses isopropyl alcohol (IPA) or another cleaning agent to pre-clean the p-type metal layer 725 prior to depositing the solution.

The solution may include the material of the self-assembled monolayer film 735 dissolved in a solvent, which enables the material of the self-assembled monolayer film 735 to be distributed across the p-type metal layer 725. The solvent may include a gamma-butyrolactone (GBL) solvent, a diethylformamide (DEF) solvent, a propylene glycol methyl ether acetate (PGMEA) solvent, a propylene glycol methyl ether (PGME) solvent, and/or another suitable solvent.

Once the p-type metal layer 725 is coated with the solvent, a spin dry operation may be performed to cure the solution by evaporating the solvent such that the material of the self-assembled monolayer film 735 remains on the p-type metal layer 725. The molecules of the material spontaneously self-assemble into a monolayer, thereby forming the self-assembled monolayer film 735. In some implementations, another cleaning operation (e.g., using IPA or another cleaning agent) is performed prior to the spin dry operation. In some implementations, the spin dry operation is performed in a range of approximately 200 revolutions per minute (rpm) to approximately 1000 rpm. However, other values and ranges for the spin dry operation are within the scope of the present disclosure.

In some implementations, the self-assembled monolayer film 735 is formed to a thickness that is included in a range of approximately 0.1 angstroms to approximately 10 angstroms. If the thickness of the self-assembled monolayer film 735 is less than approximately 0.1 angstroms, the self-assembled monolayer film 735 may not sufficiently block or inhibit formation of the n-type metal layer on the p-type metal layer 725, resulting in degradation of the work function of the p-type gate structure 710b. If the thickness of the self-assembled monolayer film 735 is greater than approximately 10 angstroms, the self-assembled monolayer film 735 may be too thick to be adequately removed from the p-type gate structure 710b. If the thickness of the self-assembled monolayer film 735 is included in the range of approximately 0.1 angstroms to approximately 10 angstroms, the self-assembled monolayer film 735 may sufficiently block or inhibit formation of the n-type metal layer on the p-type metal layer 725, and may be sufficiently removed from the p-type gate structure 710b. However, other values for the thickness of the self-assembled monolayer film 735, and ranges other than approximately 0.1 angstroms to approximately 10 angstroms, are within the scope of the present disclosure.

As shown in FIG. 7F, an n-type metal layer 750 is formed on the n-type gate structure 710a after formation of the self-assembled monolayer film 735 on p-type metal layer 725 of the p-type gate structure 710b. The n-type metal layer 750 is formed such that the n-type metal layer 750 wraps around each of the nanostructure channels 220a. The n-type metal layer 750 is also formed on the exposed portion of the mesa region 310a below the nanostructure channels 315a. A deposition tool may be used to deposit the n-type metal layer 750 using a CVD technique, a PVD technique, an ALD technique, and/or another suitable deposition technique. The n-type metal layer 750 may be deposited in one or more deposition operations.

In some embodiments, the n-type metal layer 750 wraps around the nanostructure channels 315a and is merged between vertically adjacent pairs of the nanostructure channels 315a. In some embodiments, the n-type metal layer 750 wraps around the nanostructure channels 315a and is not merged between vertically adjacent pairs of the nanostructure channels 315a. In these implementations, seams may occur in the portions of the n-type metal layer 750 between vertically adjacent pairs of the nanostructure channels 315a.

The n-type metal layer 750 includes one or more metal materials that tune or adjust the work function of the n-type gate structure 710a near the conduction band of the material of the nanostructure channels 220a. In some implementations, the n-type metal layer 750 includes titanium aluminum (TiAl). In some implementations, the n-type metal layer 750 includes titanium aluminum carbon (TiAlC). In some implementations, the n-type metal layer 750 includes another aluminum-containing metal. In some implementations, another n-type metal material is included in the n-type metal layer 750.

The n-type metal layer 750 is formed without the use of additional masking layers covering the p-type metal layer 725 of the p-type gate structure 710b. Instead, the self-assembled monolayer film 735 on the p-type metal layer 725 blocks or inhibits formation of the n-type metal layer 750 on the p-type metal layer 725. Thus, the self-assembled monolayer film 735 enables the n-type metal layer 750 to be selectively deposited on the gate dielectric layer 720 on the nanostructure channels 315a. In particular, the side chain group 745 of the material of the self-assembled monolayer film 735 inhibits adsorption of the precursors of the n-type metal layer 750 on the p-type metal layer 725.

As shown in FIG. 7G, the self-assembled monolayer film 735 may be subsequently removed after formation of the n-type metal layer 750. Various techniques may be used to remove the self-assembled monolayer film 735 from the p-type metal layer 725 of the p-type gate structure 710b. Alternatively, removal of the self-assembled monolayer film 735 may be omitted such that the self-assembled monolayer film 735 remains on the p-type metal layer 725.

In some implementations, a thermal decomposition operation may be performed to remove the self-assembled monolayer film 735 from the p-type metal layer 725 of the p-type gate structure 710b. The thermal decomposition operation may include heating the self-assembled monolayer film 735 to a temperature that is included in a range of approximately 300 degrees Celsius to approximately 500 degrees Celsius to decompose the hydrocarbon chains in the self-assembled monolayer film 735. Decomposing the side chain group 745 (e.g., the hydrocarbon chains) in the self-assembled monolayer film 735 results in desorption of the self-assembled monolayer film 735 from the p-type metal layer 725.

In some implementations, a plasma treatment operation may be performed on the self-assembled monolayer film 735 to remove the self-assembled monolayer film 735 from the p-type metal layer 725. The plasma treatment operation may include the use of a plasma (e.g., an oxygen-based plasma, a nitrogen-based plasma) to clean the surface of the p-type metal layer 725. This results in the self-assembled monolayer film 735 being stripped from the surface of the p-type metal layer 725.

In some implementations, the self-assembled monolayer film 735 is fully removed from the p-type metal layer 725. In some implementations, and as shown in FIG. 7G, removal of the self-assembled monolayer film 735 may leave behind a self-assembled monolayer film residue 755 on the p-type metal layer 725. The self-assembled monolayer film residue 755 may include residual anchoring groups 740 of the self-assembled monolayer film 735 that remain adsorbed on the surface of the p-type metal layer 725. The residual anchoring groups 740 may include ligands of one or more elements of the residual anchoring groups 740, such as sulfur (S) ligands (e.g., in implementations in which the anchoring group 740 of the self-assembled monolayer film 735 includes a thiol group), silicon (Si) ligands (e.g., in implementations in which the anchoring group 740 of the self-assembled monolayer film 735 includes a trichlorosilane (SiCl₃), and/or phosphorous (P) ligands (e.g., in implementations in which the anchoring group 740 of the self-assembled monolayer film 735 includes a phosphonate), among other examples.

In some implementations, the material of the n-type metal layer 750 is completely blocked by the self-assembled monolayer film 735 from being deposited on the p-type metal layer 725. In some implementations, the self-assembled monolayer film residue 755 also includes an n-type metal layer residue, such as in implementations in which at least a portion of the self-assembled monolayer film 735 on the p-type metal layer 725 is discontinuous and/or porous. The n-type metal layer residue may include an aluminum (Al) residue that remains on the p-type metal layer 725 of the p-type gate structure 710b after formation of the n-type metal layer 750 on the n-type gate structure 710a. However, the thickness (indicated in FIG. 7G as dimension D1) of the self-assembled monolayer film residue 755 (including the aluminum residue) on the p-type gate structure 710b is less than the thickness (indicated in FIG. 7G as dimension D2) of the n-type metal layer 750 on the n-type gate structure 710a because of the use of the self-assembled monolayer film 735 to block or inhibit deposition of the material of the n-type metal layer 750 on the p-type gate structure 710b. For example, the thickness of the n-type metal layer 750 on the n-type gate structure 710a (dimension D2) may be included in a range of approximately 5 angstroms to approximately 50 angstroms, whereas the thickness of the self-assembled monolayer film residue 755 (including the aluminum residue) on the p-type gate structure 710b (dimension D1) may be less than approximately 5 angstroms and as thin as approximately 0.1 angstroms. As a result of the minimal thickness of the self-assembled monolayer film residue 755, the self-assembled monolayer film residue 755 may be a non-continuous film (e.g., a porous film) that remains on the p-type metal layer 725. However, other values and ranges for the thickness of the self-assembled monolayer film residue 755 and for the thickness of the n-type metal layer 750 are within the scope of the present disclosure.

The lesser thickness of the self-assembled monolayer film residue 755 (including the aluminum residue) on the p-type gate structure 710b (dimension D1) results in reduced or minimal impact of the n-type metal layer 750 on the work function of the p-type gate structure 710b. In particular, the lesser thickness of the self-assembled monolayer film residue 755 (including the aluminum residue) on the p-type gate structure 710b (dimension D1) results in the work function of the p-type gate structure 710b being closer to the valence band of the material of the nanostructure channels 315b than if the self-assembled monolayer film 735 were used to block formation of the n-type metal layer 750 on the p-type gate structure 710b. Accordingly, the use of the self-assembled monolayer film 735 to block formation of the n-type metal layer 750 on the p-type gate structure 710b enables the work function of the p-type gate structure 710b to be tuned to achieve a p-type threshold voltage (PVt) for the PMOS nanostructure transistor that enables the PMOS nanostructure transistor to operate efficiently and with a low current leakage.

As shown in FIG. 7H, a gate electrode layer 760 of the n-type gate structure 710a and a gate electrode layer 760 of the p-type gate structure 710b are formed over the n-type metal layer 750 and over the p-type metal layer 725. In some implementations, the gate electrode layer 760 is formed on the self-assembled monolayer film residue 755 if the self-assembled monolayer film residue 755 remains on the p-type metal layer 725. In some implementations, separate gate electrode layers 760 are respectively formed for the n-type gate structure 710a and for the p-type gate structure 170b. In some implementations, a shared gate electrode layer 760 is formed for both the n-type gate structure 710a and for the p-type gate structure 710b. In some implementations, a glue layer is first formed on the n-type metal layer 750 and/or on the p-type metal layer 725, and the gate electrode layer 760 is formed on the glue layer. The glue layer may include titanium nitride (TiN) and/or another material that promotes adhesion of the gate electrode layer 760 to the n-type metal layer 750 and/or to the p-type metal layer 725.

The gate electrode layer 760 includes one or more metal materials, such as ruthenium (Ru), tungsten (W), cobalt (Co), copper (Cu), and/or molybdenum (Mo), among other examples. A deposition tool may be used to deposit the gate electrode layer 760 using a CVD technique, a PVD technique, an ALD technique, an electroplating technique, and/or another suitable deposition technique. The gate electrode layer 760 may be deposited in one or more deposition operations. In some implementations, a seed layer is first deposited, and the gate electrode layer 760 is deposited on the seed layer. In some implementations, a planarization tool may be used to perform a CMP operation or another type of planarization operation to planarize the gate electrode layer 760 after the gate electrode layer 760 is deposited.

In this way, the semiconductor device 105 may include a plurality of nanostructure channels 315a arranged in the z-direction that is approximately perpendicular to the semiconductor substrate 110 of the semiconductor device 105, and a plurality of nanostructure channels 315b arranged in the z-direction that is approximately perpendicular to the semiconductor substrate 110 of the semiconductor device 105. The nanostructure channels 315a and 315b may be adjacent to each other in the semiconductor device 105. The semiconductor device 105 may include an n-type gate structure 710a wrapping around the nanostructure channels 315a, and a p-type gate structure 710b wrapping around the nanostructure channels 315b. The p-type gate structure 710b may include a p-type metal layer 725 and a self-assembled monolayer film residue 755 on the p-type metal layer 725. The n-type gate structure 710a may include the n-type metal layer 750. The self-assembled monolayer film residue 755 may include one or more ligands of an anchoring group of a self-assembled monolayer film 735 that was used to block or inhibit deposition of the n-type metal layer 750 on the p-type metal layer 725, and/or may include residual material of the n-type metal layer 750.

As indicated above, FIGS. 7A-7H are provided as an example. Other examples may differ from what is described with regard to FIGS. 7A-7H.

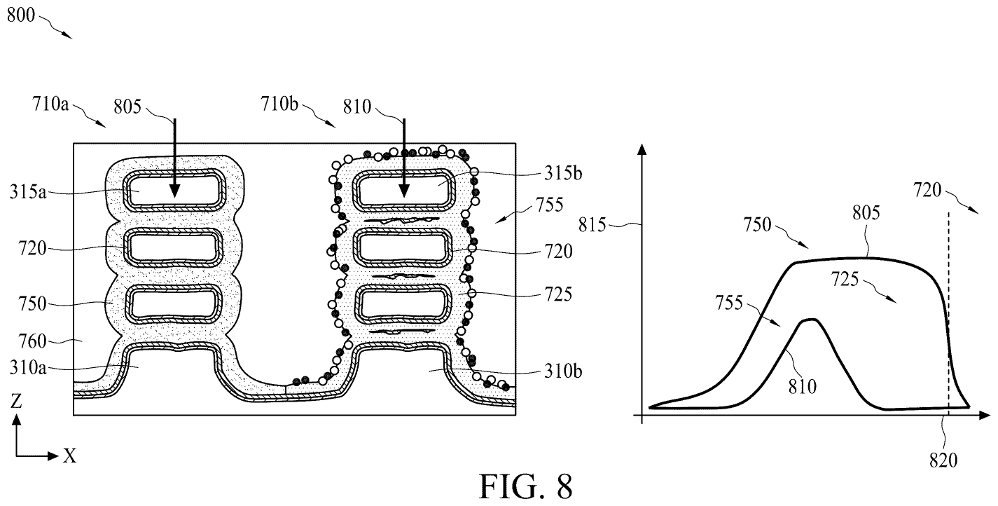

FIG. 8 is a diagram of an example 800 of elemental concentration in gate structures of a nanostructure transistor described herein. In particular, the example 800 includes an aluminum concentration 805 in an n-type gate structure 710a and an aluminum concentration 810 in a p-type gate structure 710b of a nanostructure transistor that was formed using a self-assembled monolayer film 735 to block or inhibit deposition of an n-type metal layer 750 on the p-type gate structure 710b, as described in connection with FIGS. 7A-7H.

As shown in FIG. 8, the aluminum concentrations 805 and 810 are illustrated as a function of intensity 815 and depth 820 in the n-type gate structure 710a and in the p-type gate structure 710b. The intensity 815 of the aluminum concentrations 805 is highest in the n-type metal layer 750 of the n-type gate structure 710a in that the n-type metal layer 750 is composed of an aluminum-containing n-type work function metal such as titanium aluminum (TiAl) or titanium aluminum carbide (TiAlC), among other examples. The intensity 815 of the aluminum concentrations 810 in the p-type gate structure 710b is highest in the self-assembled monolayer film residue 755 in that the self-assembled monolayer film residue 755 may include a small amount of the aluminum residue on the p-type metal layer 725. However, the intensity 815 of aluminum in the self-assembled monolayer film residue 755 is less than the intensity 815 of aluminum in the n-type metal layer 750 because of the use of the self-assembled monolayer film 735 to block or inhibit deposition of an n-type metal layer 750 on the p-type gate structure 710b.

As indicated above, FIG. 8 is provided as an example. Other examples may differ from what is described with regard to FIG. 8.

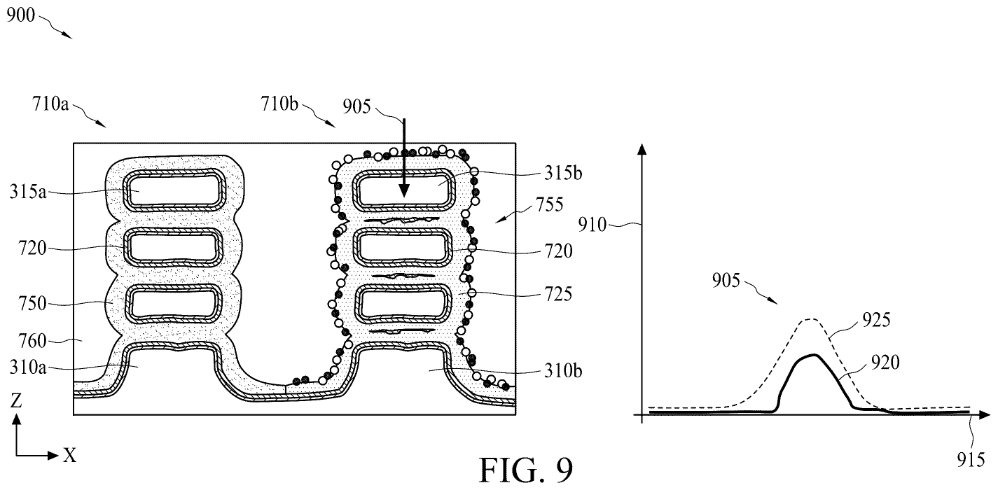

FIG. 9 is a diagram of an example 900 of elemental composition of a gate structure of a nanostructure transistor described herein. In particular, the example 900 includes an elemental composition 905 of a p-type gate structure 710b of a nanostructure transistor that was formed using a self-assembled monolayer film 735 to block or inhibit deposition of an n-type metal layer 750 on the p-type gate structure 710b, as described in connection with FIGS. 7A-7H.

As shown in FIG. 9, the elemental composition 905 is illustrated as a function of concentration 910 and depth 915 in gate p-type gate structure 710b. The elemental composition 905 includes a self-assembled monolayer film residue component 920 and an n-type metal layer residue component 925. The self-assembled monolayer film residue component 920 corresponds to the self-assembled monolayer film residue 755 that may remain on the p-type metal layer 725 of the p-type gate structure 710b after removal of the self-assembled monolayer film 735.

The self-assembled monolayer film residue component 920 may include ligands of one or more elements of an anchoring group 740 of the self-assembled monolayer film 735 that remain adsorbed on the surface of the p-type metal layer 725 after removal of the self-assembled monolayer film 735. The ligands may include, for example, sulfur (S) ligands (e.g., in implementations in which the anchoring group 740 of the self-assembled monolayer film 735 includes a thiol group), silicon (Si) ligands (e.g., in implementations in which the anchoring group 740 of the self-assembled monolayer film 735 includes a trichlorosilane (SiCl3)), and/or phosphorous (P) ligands (e.g., in implementations in which the anchoring group 740 of the self-assembled monolayer film 735 includes a phosphonate), among other examples.

The n-type metal layer residue component 925 may include aluminum (Al) residue that remains on the p-type metal layer 725 of the p-type gate structure 710b after formation of the n-type metal layer 750 on the n-type gate structure 710a. As indicated in FIG. 8, the concentration of aluminum residue on the p-type gate structure 710b is less than the concentration of aluminum on the n-type gate structure 710a because of the use of the self-assembled monolayer film 735 to block or inhibit deposition of the material of the n-type metal layer 750 on the p-type gate structure 710b.

As indicated above, FIG. 9 is provided as an example. Other examples may differ from what is described with regard to FIG. 9.

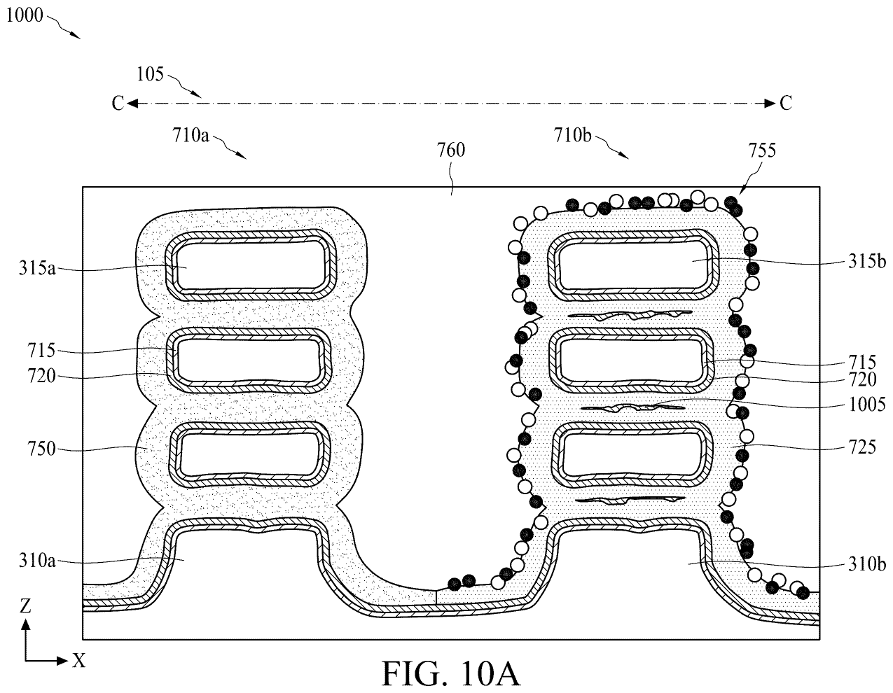

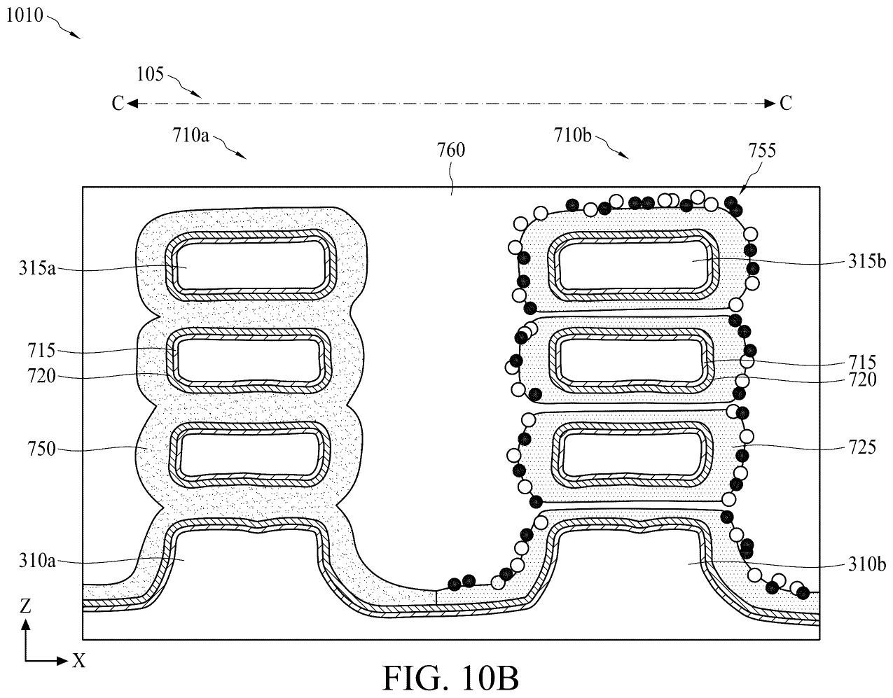

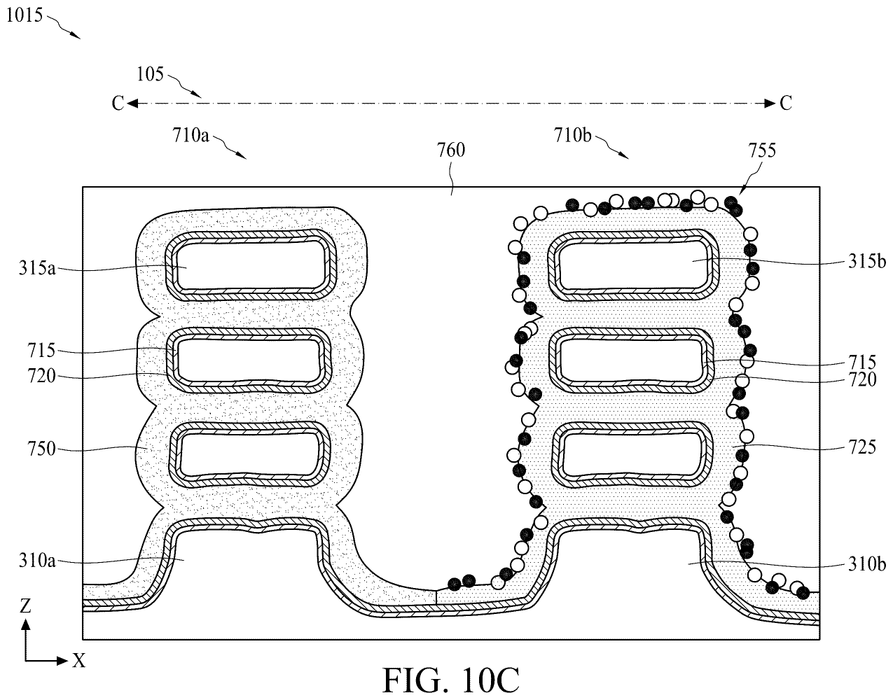

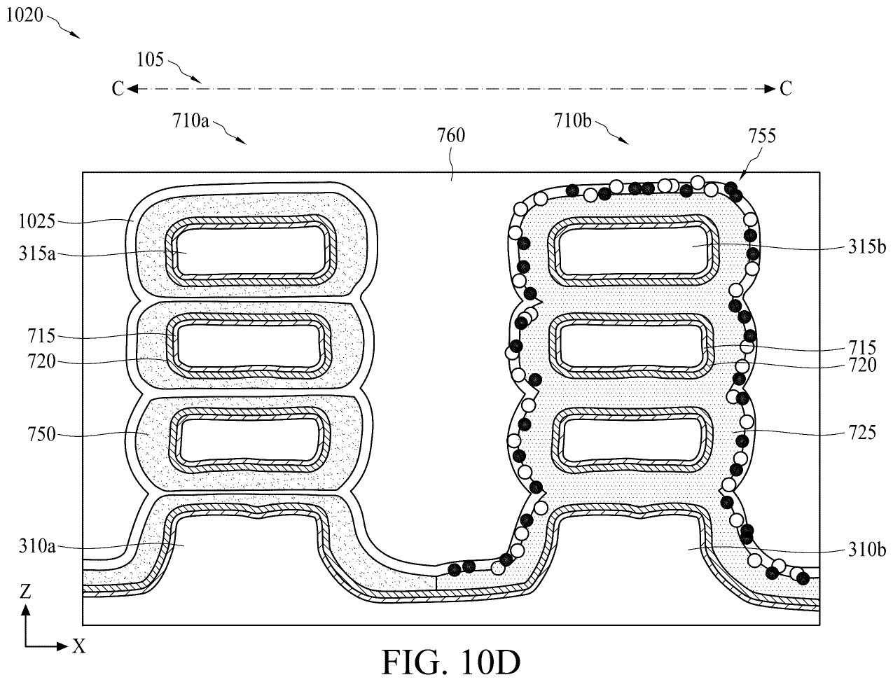

FIGS. 10A-10D are diagrams of example implementations of gate structures in a nanostructure transistor described herein. In particular, FIGS. 10A-10D illustrate various example implementations of p-type metal layers 725 (e.g., p-type work function metal layers) for the p-type gate structures 710b and/or various example implementations of n-type metal layers 750 (e.g., n-type work function metal layers) for the n-type gate structures 710a of a nanostructure transistor included in the semiconductor device 105.

FIG. 10A illustrates an example implementation 1000 in which seams 1005 occur in the p-type metal layer 725 of the p-type gate structure 710b. The seams 1005 may occur between portions of the p-type metal layer 725 that are located between vertically adjacent pairs of the nanostructure channels 315b. In some implementations, a small amount of the self-assembled monolayer film 735 described herein may be deposited in the seams 1005.

FIG. 10B illustrates an example implementation 1010 in which the p-type metal layer 725 of the p-type gate structure 710b is non-merged between vertically adjacent pairs of the nanostructure channels 315b. In some implementations, the space between the portions of the p-type metal layer 725 on vertically adjacent pairs of the nanostructure channels 315b is filled in with another p-type metal layer. In some implementations, the space between the portions of the p-type metal layer 725 on vertically adjacent pairs of the nanostructure channels 315b is filled in with the gate electrode layer 760. In some implementations, a small amount of the self-assembled monolayer film 735 described herein may be deposited in the space between the portions of the p-type metal layer 725 that are located on vertically adjacent pairs of the nanostructure channels 315b.

FIG. 10C illustrates an example implementation 1015 in which the p-type metal layer 725 of the p-type gate structure 710b is fully merged in the spaces between vertically adjacent pairs of the nanostructure channels 315b.

FIG. 10D illustrates an example implementation 1020 in which a glue layer 1025 may be included on the n-type metal layer 750 of the n-type gate structure 710a, and on the p-type metal layer 725 of the p-type gate structure 710b (including on the self-assembled monolayer film residue 755). The glue layer 1025 may include titanium nitride (TiN) and/or another suitable material to facilitate adhesion between the n-type metal layer 750 and the gate electrode layer 760, and/or to facilitate adhesion between the p-type metal layer 725 and the gate electrode layer 760.

As further shown in the example implementation 1020 in FIG. 10D, the n-type metal layer 750 of the n-type gate structure 710a is non-merged between vertically adjacent pairs of the nanostructure channels 315a. In some implementations, the glue layer 1025 fills in the gaps between portions of the n-type metal layer 750 that are between vertically adjacent pairs of the nanostructure channels 315b.

As indicated above, FIGS. 10A-10D are provided as examples. Other examples may differ from what is described with regard to FIGS. 10A-10D.

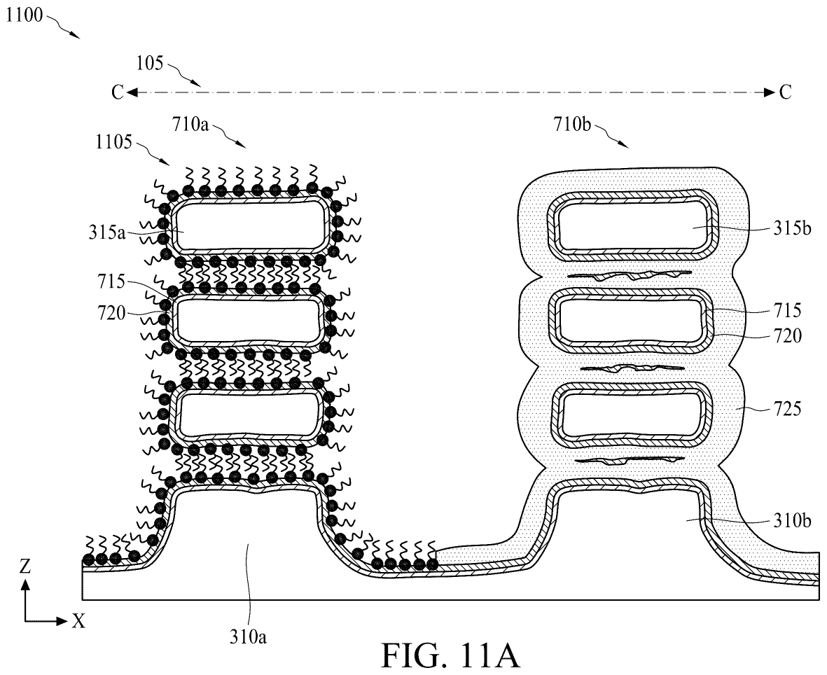

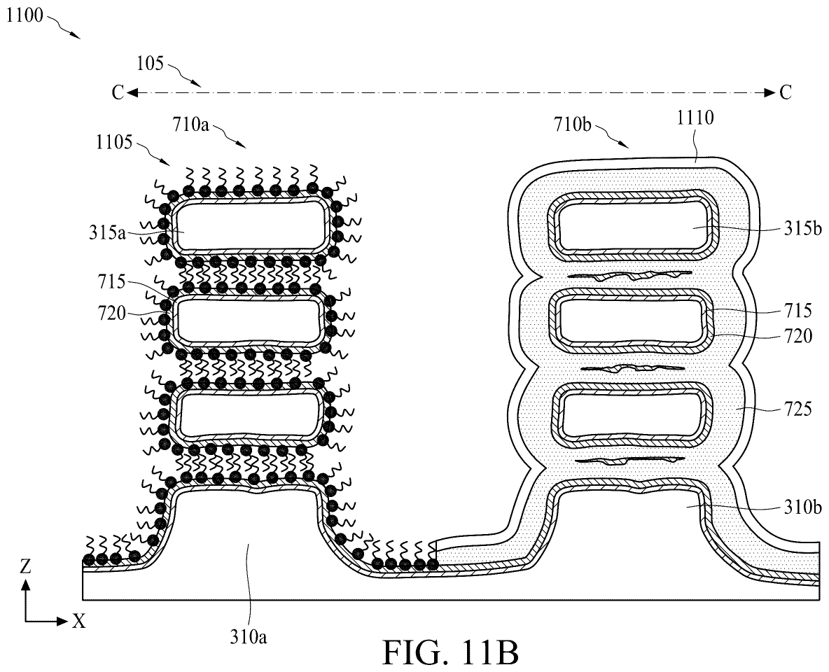

FIGS. 11A and 11B are diagrams of an example implementation 1100 of forming work function metal layers of a gate structure of a nanostructure transistor described herein. As shown in FIG. 11A, the example implementation 1100 includes forming a self-assembled monolayer film 1105, similarly as described in connection with FIG. 7E. However, in the example implementation 1100, the self-assembled monolayer film 1105 is formed on the gate dielectric layer 720 of the n-type gate structure 710a, as shown in FIG. 11A, instead of being formed on the p-type metal layer 725 of the p-type gate structure 710b as shown in FIG. 7E. Thus, in the example implementation 1100 the self-assembled monolayer film 1105 includes one or more materials that facilitate selective deposition of the self-assembled monolayer film 1105 on the gate dielectric layer 720 and that resist or inhibit deposition of the self-assembled monolayer film 1105 on the p-type metal layer 725 of the p-type gate structure 710b. In some implementations, the self-assembled monolayer film 1105 is formed to a thickness that is included in a range of greater than 0 angstroms and less than or approximately equal to 2 angstroms. However, other values and ranges for the thickness of the self-assembled monolayer film 1105 are within the scope of the present disclosure.

As shown in FIG. 11B, the formation of the self-assembled monolayer film 1105 on the gate dielectric layer 720 of the n-type gate structure 710a enables additional layers to be deposited on the p-type gate structure 710b while the self-assembled monolayer film 1105 blocks or inhibits deposition of the additional layers on the n-type gate structure 710a. In this way, the self-assembled monolayer film 1105 facilitates selective formation of the additional layers on the p-type gate structure 710b. In some implementations, the additional layers include additional p-type work function layers. For example, the self-assembled monolayer film 1105 blocks or inhibits deposition of another p-type metal layer 1110 on the n-type gate structure 710a, which enables the p-type metal layer 1110 to be selectively formed on the p-type metal layer 725 of the p-type gate structure 710b.

In some implementations, the self-assembled monolayer film 1105 is subsequently removed, and the operations described in connection with FIGS. 7E-7H are performed to use another self-assembled monolayer film 735 to selectively form the n-type metal layer 750 on the n-type gate structure 710a while the self-assembled monolayer film 735 blocks or inhibits deposition of the n-type metal layer 750 on the p-type metal layer 1110 of the p-type gate structure 710b.

As indicated above, FIGS. 11A and 11B are provided as an example. Other examples may differ from what is described with regard to FIGS. 11A and 11B.

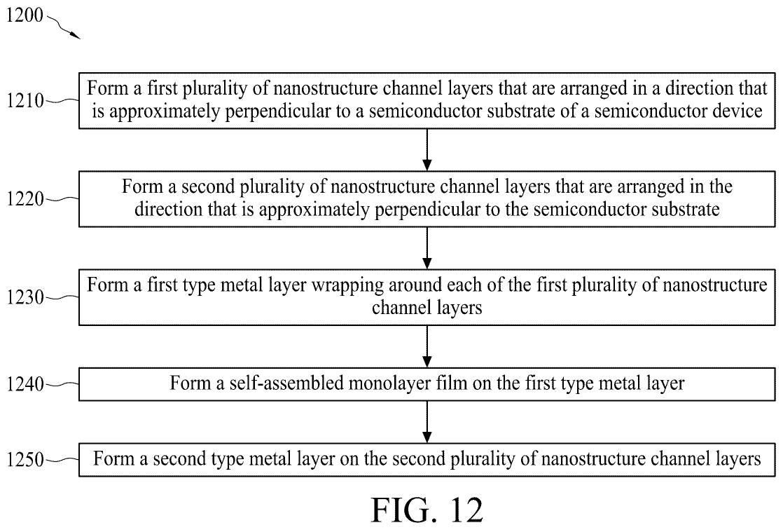

FIG. 12 is a flowchart of an example process 1200 associated with forming a semiconductor device described herein. In some implementations, one or more process blocks of FIG. 12 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 12, process 1200 may include forming a first plurality of nanostructure channel layers that are arranged in a direction that is approximately perpendicular to a semiconductor substrate of a semiconductor device (block 1210). For example, one or more semiconductor processing tools may be used to form a first plurality of nanostructure channel layers (e.g., nanostructure channels 315b) that are arranged in a direction (e.g., a z-direction) that is approximately perpendicular to a semiconductor substrate (e.g., a semiconductor substrate 110) of a semiconductor device (e.g., a semiconductor device 105), as described herein.

As further shown in FIG. 12, process 1200 may include forming a second plurality of nanostructure channel layers that are arranged in the direction that is approximately perpendicular to the semiconductor substrate (block 1220). For example, one or more semiconductor processing tools may be used to form a second plurality of nanostructure channel layers (e.g., nanostructure channels 315a) that are arranged in the direction that is approximately perpendicular to the semiconductor substrate, as described herein.

As further shown in FIG. 12, process 1200 may include forming a first type metal layer wrapping around each of the first plurality of nanostructure channel layers (block 1230). For example, one or more semiconductor processing tools may be used to form a first type metal layer (e.g., a p-type metal layer 725) wrapping around each of the first plurality of nanostructure channel layers, as described herein.

As further shown in FIG. 12, process 1200 may include forming a self-assembled monolayer film on the first type metal layer (block 1240). For example, one or more semiconductor processing tools may be used to form a self-assembled monolayer film (e.g., a self-assembled monolayer film 735) on the first type metal layer, as described herein.

As further shown in FIG. 12, process 1200 may include forming a second type metal layer on the second plurality of nanostructure channel layers (block 1250). For example, one or more semiconductor processing tools may be used to form a second type metal layer (e.g., an n-type metal layer 750) on the second plurality of nanostructure channel layers, as described herein. In some implementations, the self-assembled monolayer film inhibits formation of the second type metal layer on the first type metal layer.

Process 1200 may include additional implementations, such as any single implementation or any combination of implementations described below and/or in connection with one or more other processes described elsewhere herein.

In a first implementation, forming the self-assembled monolayer film includes depositing, by spin coating, a solution that contains material of the self-assembled monolayer film, and performing a spin dry operation to cure the solution to form the self-assembled monolayer film.

In a second implementation, alone or in combination with the first implementation, process 1200 includes removing the self-assembled monolayer film after forming the second type metal layer.

In a third implementation, alone or in combination with one or more of the first and second implementations, a residue (e.g., a self-assembled monolayer film residue 755) from the self-assembled monolayer film remains on the first type metal layer after removal of the self-assembled monolayer film.

In a fourth implementation, alone or in combination with one or more of the first through third implementations, removing the self-assembled monolayer film includes performing a thermal decomposition operation on the self-assembled monolayer film to decompose hydrocarbon chains of the self-assembled monolayer film.

In a fifth implementation, alone or in combination with one or more of the first through fourth implementations, performing the thermal decomposition operation includes heating the self-assembled monolayer film to a temperature that is included in a range of approximately 300 degrees Celsius to approximately 500 degrees Celsius.

In a sixth implementation, alone or in combination with one or more of the first through fifth implementations, removing the self-assembled monolayer film includes performing a plasma treatment operation on the self-assembled monolayer film to remove the self-assembled monolayer film.

In a seventh implementation, alone or in combination with one or more of the first through sixth implementations, forming the self-assembled monolayer film includes forming the self-assembled monolayer film as a discontinuous thin film.

Although FIG. 12 shows example blocks of process 1200, in some implementations, process 1200 includes additional blocks, fewer blocks, different blocks, or differently arranged blocks than those depicted in FIG. 12. Additionally, or alternatively, two or more of the blocks of process 1200 may be performed in parallel.

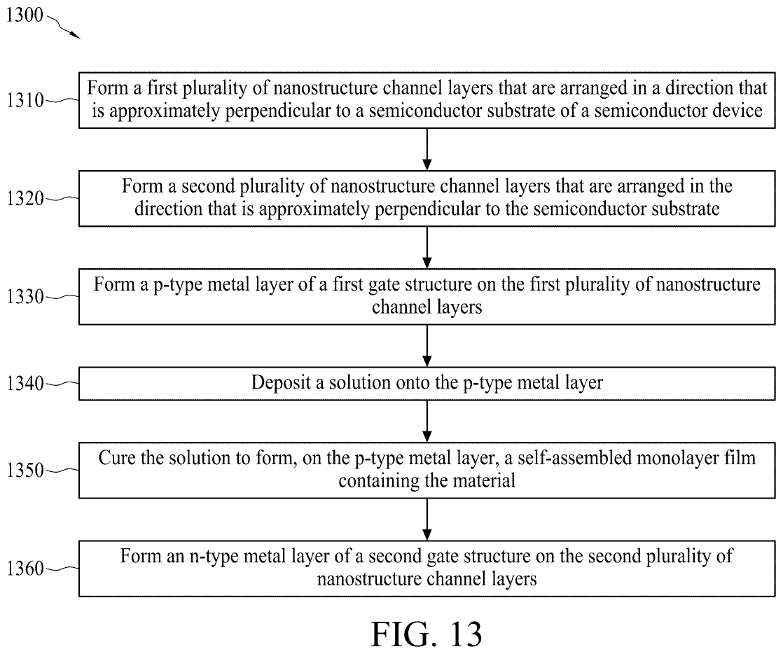

FIG. 13 is a flowchart of an example process 1300 associated with forming a semiconductor device described herein. In some implementations, one or more process blocks of FIG. 13 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 13, process 1300 may include forming a first plurality of nanostructure channel layers that are arranged in a direction that is approximately perpendicular to a semiconductor substrate of a semiconductor device (block 1310). For example, one or more semiconductor processing tools may be used to form a first plurality of nanostructure channel layers (e.g., nanostructure channels 315b) that are arranged in a direction (z-direction) that is approximately perpendicular to a semiconductor substrate (e.g., a semiconductor substrate 110) of a semiconductor device (e.g., a semiconductor device 105), as described herein.

As further shown in FIG. 13, process 1300 may include forming a second plurality of nanostructure channel layers that are arranged in the direction that is approximately perpendicular to the semiconductor substrate (block 1320). For example, one or more semiconductor processing tools may be used to form a second plurality of nanostructure channel layers (e.g., nanostructure channels 315a) that are arranged in the direction that is approximately perpendicular to the semiconductor substrate, as described herein.

As further shown in FIG. 13, process 1300 may include forming a p-type metal layer of a first gate structure on the first plurality of nanostructure channel layers (block 1330). For example, one or more semiconductor processing tools may be used to form a p-type metal layer (e.g., a p-type metal layer 725) of a first gate structure (e.g., a p-type gate structure 710b) on the first plurality of nanostructure channel layers, as described herein.

As further shown in FIG. 13, process 1300 may include depositing a solution onto the p-type metal layer (block 1340). For example, one or more semiconductor processing tools may be used to deposit a solution onto the p-type metal layer, as described herein. In some implementations, the solution comprises a material that is dissolved in a solvent.

As further shown in FIG. 13, process 1300 may include curing the solution to form, on the p-type metal layer, a self-assembled monolayer film containing the material (block 1350). For example, one or more semiconductor processing tools may be used to cure the solution to form, on the p-type metal layer, a self-assembled monolayer film (e.g., a self-assembled monolayer film 735) containing the material, as described herein.

As further shown in FIG. 13, process 1300 may include forming an n-type metal layer of a second gate structure on the second plurality of nanostructure channel layers (block 1360). For example, one or more semiconductor processing tools may be used to form an n-type metal layer (e.g., an n-type metal layer 750) of a second gate structure (e.g., an n-type gate structure 710a) on the second plurality of nanostructure channel layers, as described herein. In some implementations, the material of the self-assembled monolayer film comprises a side chain group (e.g., a side chain group 745) that inhibits adsorption of the n-type metal layer on the p-type metal layer.

Process 1300 may include additional implementations, such as any single implementation or any combination of implementations described below and/or in connection with one or more other processes described elsewhere herein.

In a first implementation, the material of the self-assembled monolayer film includes an anchoring group (e.g., an anchoring group 740) that promotes adsorption of the material of the self-assembled monolayer film on the p-type metal layer.

In a second implementation, alone or in combination with the first implementation, the anchoring group includes at least one of an amino group, a thiol group, a carboxyl group, a carbonyl group, a trichlorosilane (SiCl₃), or a phosphonate.

In a third implementation, alone or in combination with one or more of the first and second implementations, the side chain group includes an aryl group hydrocarbon chain.

In a fourth implementation, alone or in combination with one or more of the first through third implementations, process 1300 includes removing the self-assembled monolayer film after forming the n-type metal layer, where a self-assembled monolayer film residue (e.g., a self-assembled monolayer film residue 755) remains on the p-type metal layer after removal of the self-assembled monolayer film.

In a fifth implementation, alone or in combination with one or more of the first through fourth implementations, the self-assembled monolayer film residue includes at least one of a sulfur (S) ligand, a silicon (Si) ligand, or a phosphorous (P) ligand.

In a sixth implementation, alone or in combination with one or more of the first through fifth implementations, a thickness (e.g., a dimension D1) of the self-assembled monolayer film residue is less than a thickness (e.g., a dimension D2) of the n-type metal layer on the second plurality of nanostructure channel layers.

In a seventh implementation, alone or in combination with one or more of the first through sixth implementations, the solvent includes at least one of a gamma-butyrolactone (GBL) solvent, a diethylformamide (DEF) solvent, a propylene glycol methyl ether acetate (PGMEA) solvent, or a propylene glycol methyl ether (PGME) solvent.

Although FIG. 13 shows example blocks of process 1300, in some implementations, process 1300 includes additional blocks, fewer blocks, different blocks, or differently arranged blocks than those depicted in FIG. 13. Additionally, or alternatively, two or more of the blocks of process 1300 may be performed in parallel.

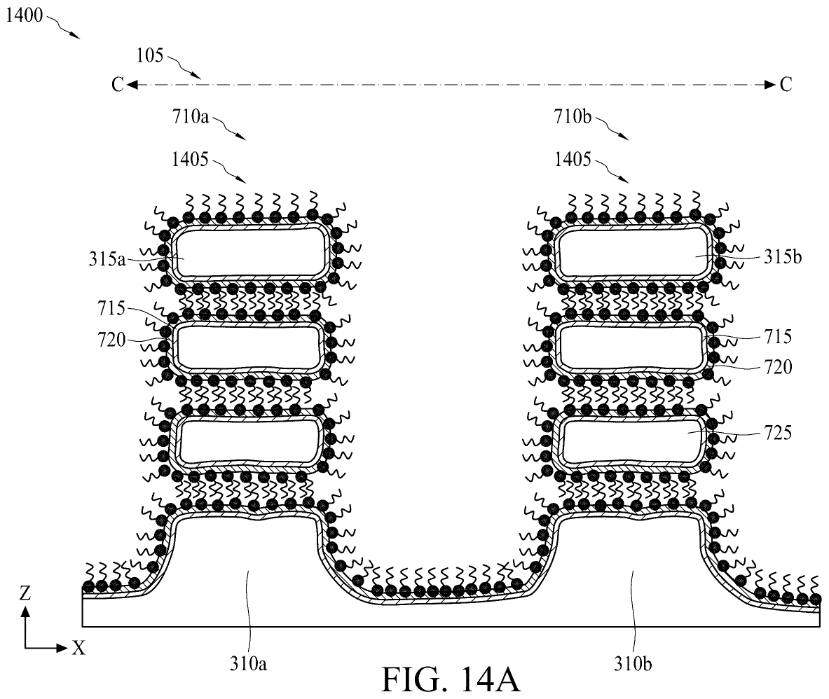

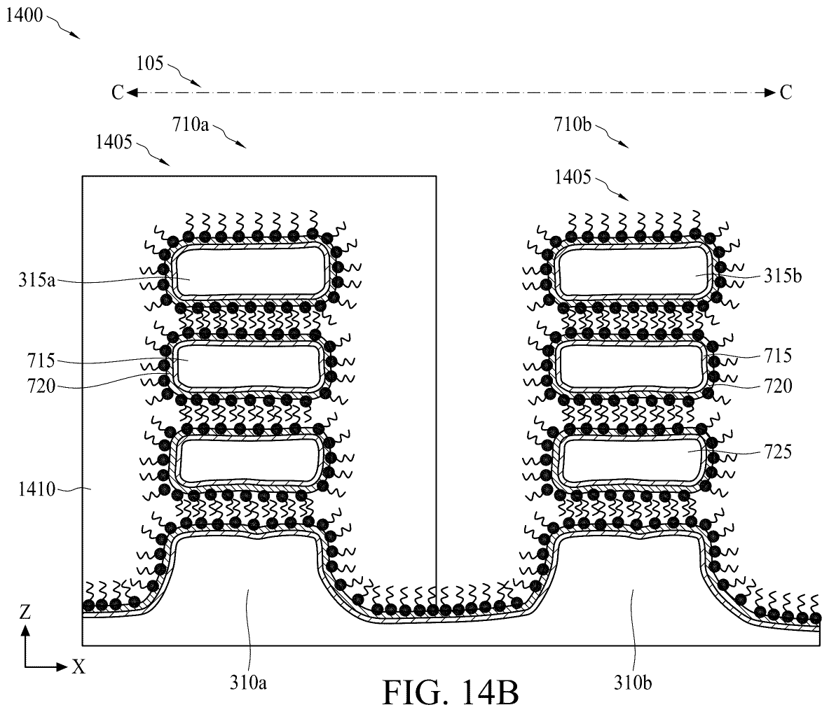

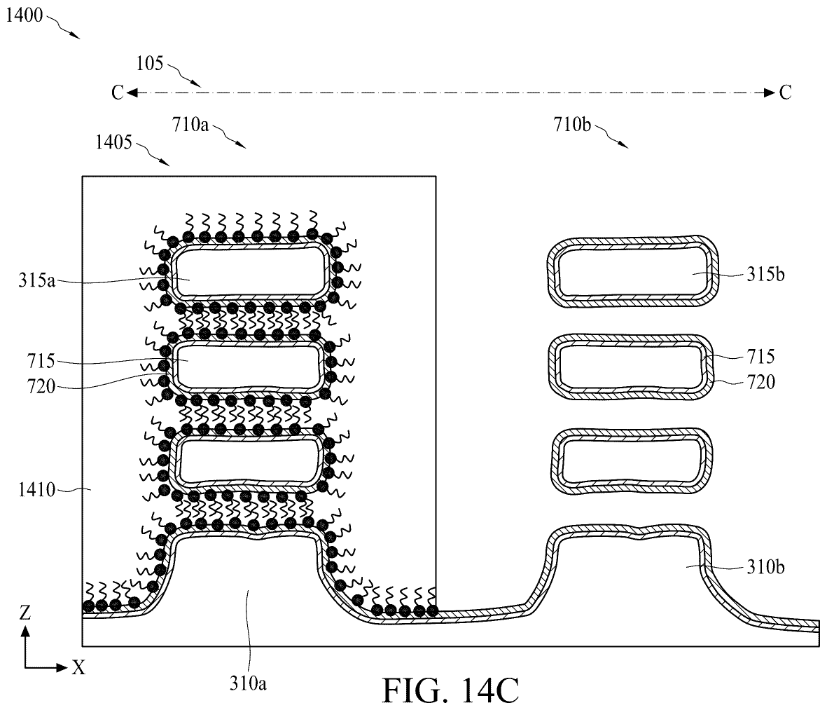

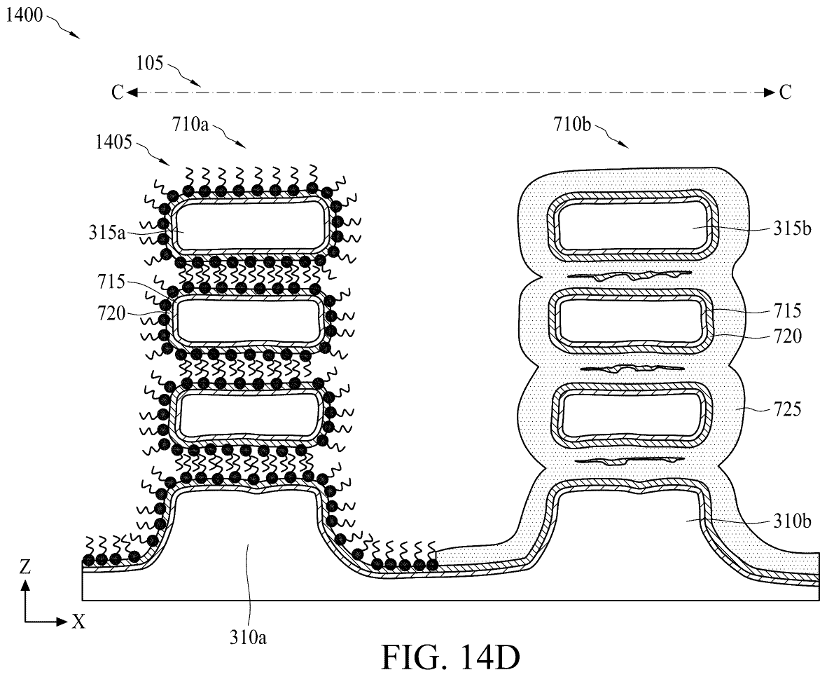

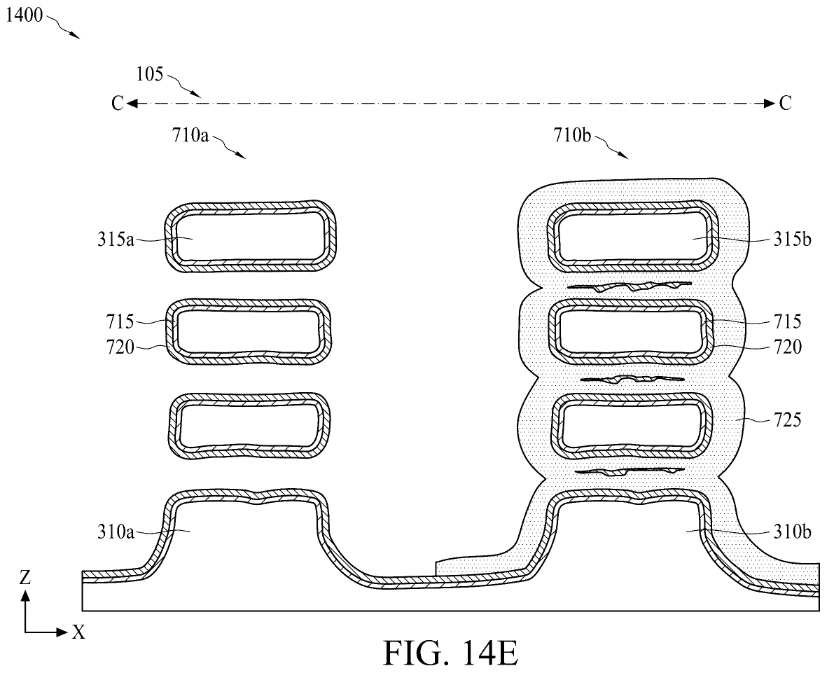

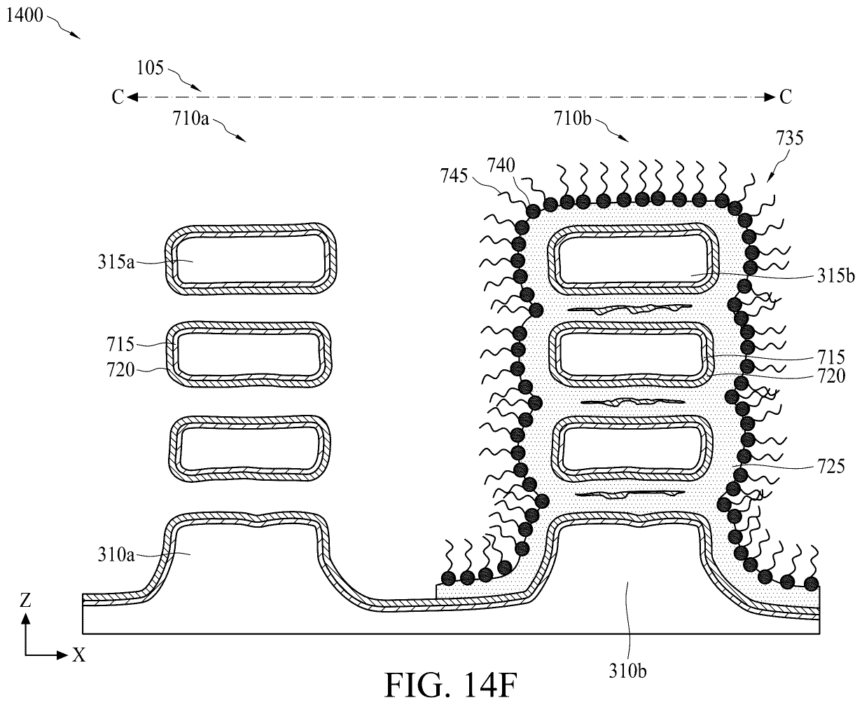

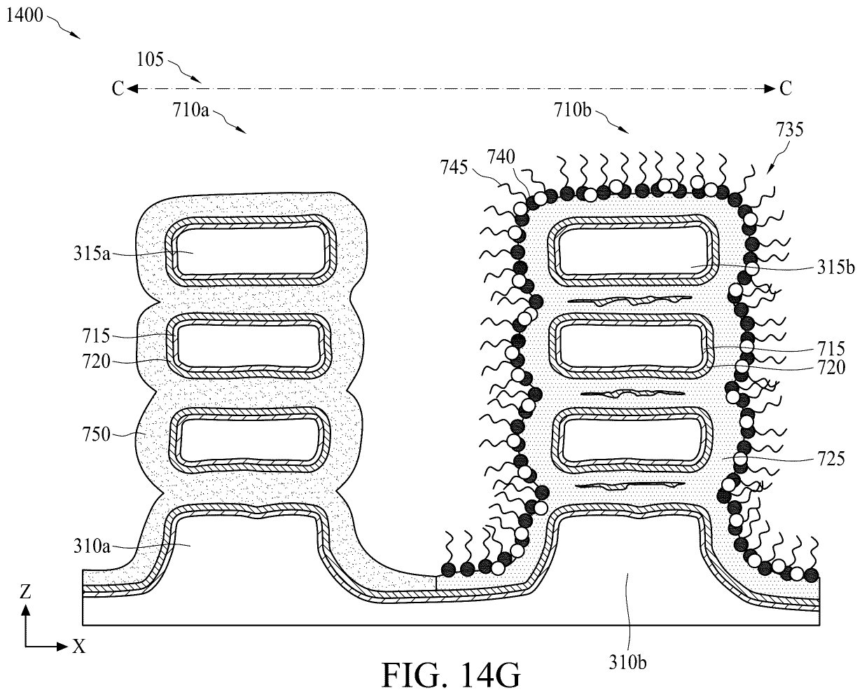

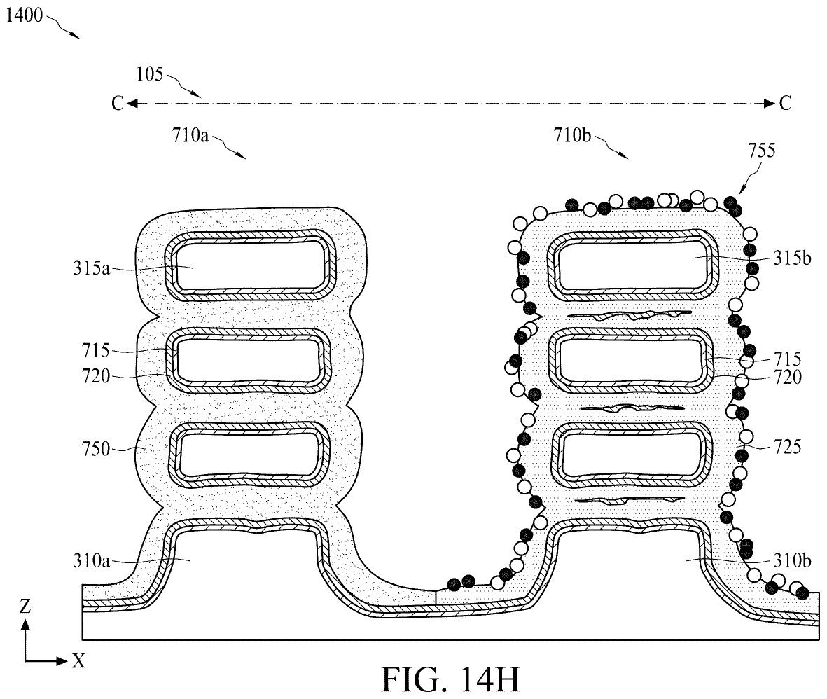

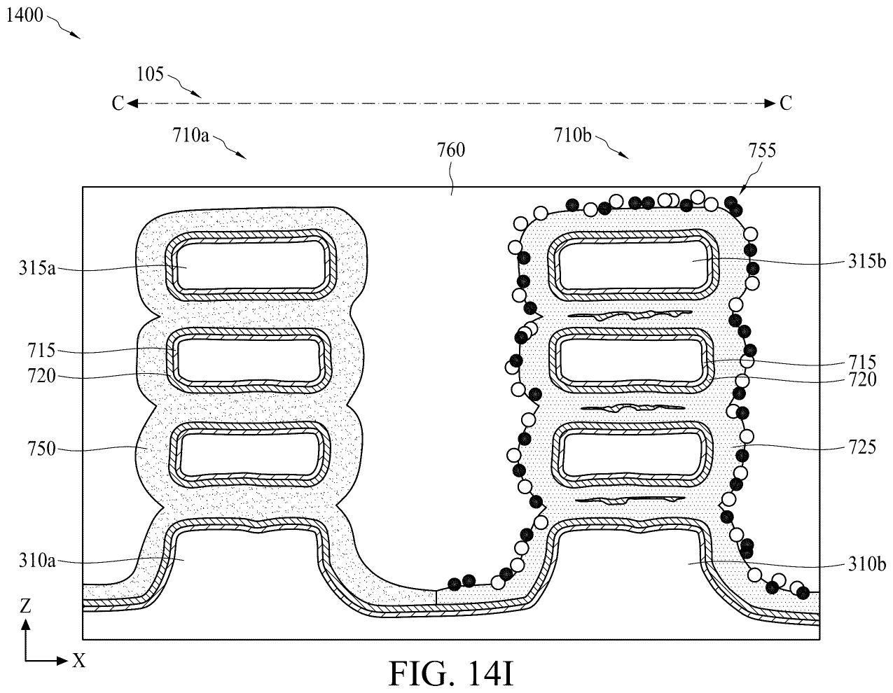

FIGS. 14A-14I are diagrams of an example implementation 1400 of forming work function metal layers of a gate structure of a nanostructure transistor described herein. The example implementation 1400 includes an example of using different self-assembled monolayer films for the n-type gate structure 710a and p-type gate structure 710b to inhibit growth of opposing metal layer types. For example, as described in connection with FIGS. 14A-14I, a first self-assembled monolayer film may be formed on the n-type gate structure 710a to inhibit growth of a p-type metal layer 725 on the n-type gate structure 710a, and a second (different) self-assembled monolayer film may be formed on the p-type gate structure 710b to inhibit growth of the n-type metal layer 750 on the p-type gate structure 710b.

As shown in FIG. 14A, the example implementation 1400 includes forming a self-assembled monolayer film 1405 on the gate dielectric layer 720 of the n-type gate structure 710a and on the gate dielectric layer 720 of the p-type gate structure 710b, as shown in FIG. 14A. Thus, in the example implementation 1400 the self-assembled monolayer film 1405 includes one or more materials that facilitate selective deposition of the self-assembled monolayer film 1405 on the gate dielectric layer 720. For example, the self-assembled monolayer film 1405 may include an anchoring group that promotes adsorption to the material of the gate dielectric layer 720.

In some implementations, the material of the self-assembled monolayer film 1405 is resistant to adsorption of precursors of the p-type metal layer 725 that is to be formed for the p-type gate structure 710b. For example, the material of the self-assembled monolayer film 1405 may include a side chain group that is resistant to adsorption of titanium nitride (TiN) precursors such as titanium tetrachloride (TiCl₄) and/or ammonia (NH₃), among other examples. In this way, the self-assembled monolayer film 1405 may be used to inhibit growth of the p-type metal layer 725 on the n-type metal gate structure 710a.

As shown in FIG. 14B, a masking layer 1410 is formed on the n-type gate structure 710a. The masking layer 140 may include a photoresist layer that is formed using a deposition tool (e.g., using a spin-coating technique). Alternatively, the masking layer 1410 may include another type masking layer and may be formed using another deposition technique.

As shown in FIG. 14C, the self-assembled monolayer film 1405 is removed from the p-type gate structure 710b while the masking layer 1410 protects the self-assembled monolayer film 1405 on the n-type gate structure 710a. In other words, the self-assembled monolayer film 1405 is selectively removed from the p-type gate structure 710b such that the self-assembled monolayer film 1405 remains on the n-type gate structure 710a. The self-assembled monolayer film 1405 may be removed using one or more techniques described in connection with FIG. 7G. In some implementations, self-assembled monolayer film 1405 may be removed using another technique.

As further shown in FIG. 14D, the p-type metal layer 725 is selectively formed on the gate dielectric layer 720 of the nanostructure channels 315b but not on the nanostructure channels 315 since the self-assembled monolayer film 1405 blocks or inhibits growth of the p-type metal layer 725 on the nanostructure channels 315a (e.g., on which the n-type metal layer 750 is to be formed).

The use of the self-assembled monolayer film 1405 to form the p-type metal layer 725 on the nanostructure channels 315b and not on the nanostructure channels 315a enables the p-type metal layer 725 to be selectively formed on the nanostructure channels 315b without the use of subsequent patterning and etching steps for forming a masking layer over the p-type metal layer 725 on the nanostructure channels 315b and etching the p-type metal layer 725 on the nanostructure channels 315a to remove the p-type metal layer 725 from the nanostructure channels 315a. This prevents residual material of the p-type metal layer 725 from remaining on the nanostructure channels 315a. The residual material of the p-type metal layer 725 might otherwise remain on the nanostructure channels 315a because of incomplete removal of the p-type metal layer 725 from the nanostructure channels 315b.

The self-assembled monolayer film 1405 enables the p-type metal layer 725 to be selectively formed on the nanostructure channels 315b because the material and the monolayer structure of the self-assembled monolayer film 1405 inhibits precursors of the material of the p-type metal layer 725 from being adsorbed onto the surface of the gate dielectric layer 720 that is on the nanostructure channels 315a. For example, the material of the self-assembled monolayer film 1405 inhibits adsorption of precursors such as titanium tetrachloride (TiCl₄) and/or ammonia (NH₃), which may adsorb onto the surface of the gate dielectric layer 720 on the nanostructure channels 315b and react to form titanium nitride (TiN) for the p-type metal layer 725. In particular, the chemical incompatibility between the side chain group of the material of the self-assembled monolayer film 1405 and the precursors of the material of the p-type metal layer 725, alone or in combination with the surface blocking provided by the dense molecular monolayer structure of the self-assembled monolayer film 1405, may inhibit adsorption of the precursors of the material of the p-type metal layer 725.

As shown in FIG. 14E, the self-assembled monolayer film 1405 is removed from the n-type gate structure 710a after formation of the p-type metal layer 725 on the gate dielectric layer 720 of the p-type gate structure 710b. The self-assembled monolayer film 1405 may be removed using one or more techniques described in connection with FIG. 7G. In some implementations, self-assembled monolayer film 1405 may be removed using another technique.

As shown in FIG. 14F, a self-assembled monolayer film 735 is formed on the p-type metal layer 725 of the p-type gate structure 710b. The self-assembled monolayer film 735 may include a different material than the material of the self-assembled monolayer film 1405. This enables the self-assembled monolayer film 735 to be selectively deposited on the p-type metal layer 725 with minimal to no deposition of the self-assembled monolayer film 735 on the gate dielectric layer 720 of the n-type gate structure 710a. Moreover, the material of the self-assembled monolayer film 735 may be resistant to adsorption of precursors of the n-type metal layer 750 that is to be formed for the n-type gate structure 710a. For example, the material of the self-assembled monolayer film 735 may be resistant to adsorption of titanium aluminum carbon (TiAlC) precursors such as titanium tetrachloride (TiCl₄) and/or triethyaluminum (Al₂(C₂H₅)₆ or TEA), among other examples. In this way, the self-assembled monolayer film 735 may be used to inhibit growth of the n-type metal layer 750 on the p-type metal gate structure 710b. For example, the self-assembled monolayer film 735 may include one or more materials described in connection with FIG. 7E.

As shown in FIG. 14G, the n-type metal layer 750 is formed on the n-type gate structure 710a after formation of the self-assembled monolayer film 735 on p-type metal layer 725 of the p-type gate structure 710b. The self-assembled monolayer film 735 on the p-type metal layer 725 blocks or inhibits formation of the n-type metal layer 750 on the p-type metal layer 725. Thus, the self-assembled monolayer film 735 enables the n-type metal layer 750 to be selectively deposited on the gate dielectric layer 720 on the nanostructure channels 315a. The n-type metal layer 750 may be formed as described in connection with FIG. 7F.

As shown in FIG. 14H, the self-assembled monolayer film 735 may be subsequently removed after formation of the n-type metal layer 750. For example, one or more techniques described in connection with FIG. 7G may be used to fully or partially remove the self-assembled monolayer film 735.

As shown in FIG. 14I, the gate electrode layer 760 of the n-type gate structure 710a and a gate electrode layer 760 of the p-type gate structure 710b are formed over the n-type metal layer 750 and over the p-type metal layer 725. The gate electrode layer 760 may be formed in a similar manner as described above in connection with FIG. 7H.

As indicated above, FIGS. 14A-14I are provided as an example. Other examples may differ from what is described with regard to FIGS. 14A-14I.

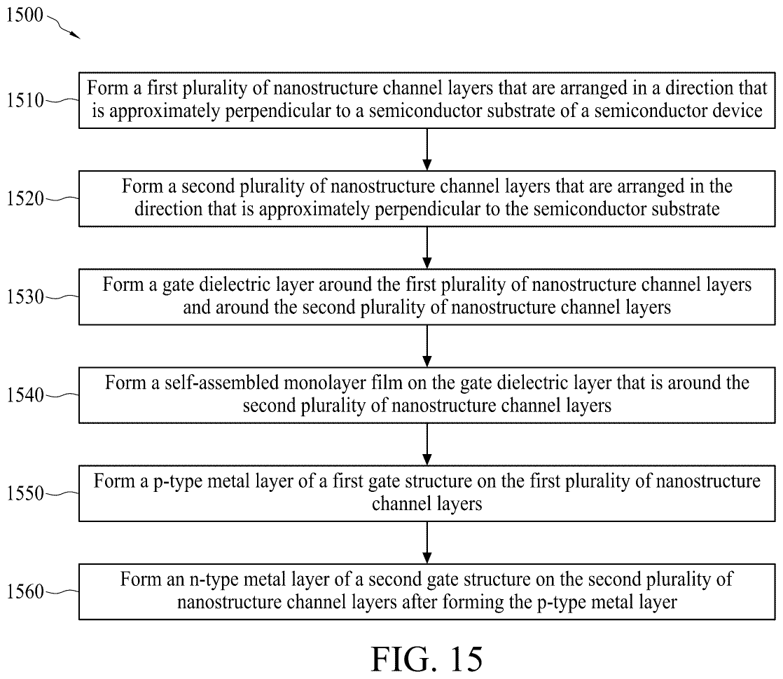

FIG. 15 is a flowchart of an example process 1500 associated with forming a semiconductor device described herein. In some implementations, one or more process blocks of FIG. 15 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 15, process 1500 may include forming a first plurality of nanostructure channel layers that are arranged in a direction that is approximately perpendicular to a semiconductor substrate of a semiconductor device (block 1510). For example, one or more semiconductor processing tools may be used to form a first plurality of nanostructure channel layers (e.g., nanostructure channels 315b) that are arranged in a direction (z-direction) that is approximately perpendicular to a semiconductor substrate (e.g., a semiconductor substrate 110) of a semiconductor device (e.g., a semiconductor device 105), as described herein.

As further shown in FIG. 15, process 1500 may include forming a second plurality of nanostructure channel layers that are arranged in the direction that is approximately perpendicular to the semiconductor substrate (block 1520). For example, one or more semiconductor processing tools may be used to form a second plurality of nanostructure channel layers (e.g., nanostructure channels 315a) that are arranged in the direction that is approximately perpendicular to the semiconductor substrate, as described herein.

As further shown in FIG. 15, process 1500 may include forming a gate dielectric layer around the first plurality of nanostructure channel layers and around the second plurality of nanostructure channel layers (block 1530). For example, one or more semiconductor processing tools may be used to form a gate dielectric layer (e.g., a gate dielectric layer 720) around the first plurality of nanostructure channel layers and around the second plurality of nanostructure channel layers, as described herein.

As further shown in FIG. 15, process 1500 may include forming a self-assembled monolayer film on the gate dielectric layer that is around the second plurality of nanostructure channel layers (block 1540). For example, one or more semiconductor processing tools may be used to form a self-assembled monolayer film (e.g., a self-assembled monolayer film 1405) on the gate dielectric layer that is around the second plurality of nanostructure channel layers, as described herein.

As further shown in FIG. 15, process 1500 may include forming a p-type metal layer of a first gate structure on the first plurality of nanostructure channel layers (block 1550). For example, one or more semiconductor processing tools may be used to form a p-type metal layer (e.g., a p-type metal layer 725) of a first gate structure (e.g., a p-type gate structure 710b) on the first plurality of nanostructure channel layers, as described herein. In some implementations, the material of the self-assembled monolayer film inhibits adsorption of the p-type metal layer on the gate dielectric layer that is around the second plurality of nanostructure channel layers.

As further shown in FIG. 15, process 1500 may include forming an n-type metal layer of a second gate structure on the second plurality of nanostructure channel layers after forming the p-type metal layer (block 1560). For example, one or more semiconductor processing tools may be used to form an n-type metal layer (e.g., an n-type metal layer 750) of a second gate structure (e.g., an n-type gate structure 710a) on the second plurality of nanostructure channel layers after forming the p-type metal layer, as described herein.

Process 1500 may include additional implementations, such as any single implementation or any combination of implementations described below and/or in connection with one or more other processes described elsewhere herein.

In a first implementation, the self-assembled monolayer film is a first self-assembled monolayer film, and the process 1500 includes depositing a solution onto the p-type metal layer that is on the first plurality of nanostructure channels prior to forming the n-type metal layer, wherein the solution includes a material that is dissolved in a solvent, curing the solution to form, on the p-type metal layer, a second self-assembled monolayer film (e.g., a self-assembled monolayer film 735) containing the material, where the material of the second self-assembled monolayer film includes a side chain group (e.g., a side chain group 745) that inhibits adsorption of the n-type metal layer on the p-type metal layer.

In a second implementation, alone or in combination with the first implementation, the material of the self-assembled monolayer film includes an anchoring group (e.g., an anchoring group 740) that promotes adsorption of the material of the self-assembled monolayer film on the p-type metal layer, and wherein the anchoring group comprises at least one of an amino group, a thiol group, a carboxyl group, a carbonyl group, a trichlorosilane (SiCl³), or a phosphonate.

In a third implementation, alone or in combination with one or more of the first and second implementations, process 1500 includes removing the second self-assembled monolayer film after forming the n-type metal layer, where a self-assembled monolayer film residue (e.g., a self-assembled monolayer film residue 755) remains on the p-type metal layer after removal of the second self-assembled monolayer film, and where the second self-assembled monolayer film residue includes at least one of a sulfur (S) ligand, a silicon (Si) ligand, or a phosphorous (P) ligand.

In a fourth implementation, alone or in combination with one or more of the first through third implementations, the solvent includes at least one of a gamma-butyrolactone (GBL) solvent, a diethylformamide (DEF) solvent, a propylene glycol methyl ether acetate (PGMEA) solvent, or a propylene glycol methyl ether (PGME) solvent.

In a fifth implementation, alone or in combination with one or more of the first through fourth implementations, process 1500 includes removing the self-assembled monolayer film from the gate dielectric layer that is around the second plurality of nanostructure channel layers prior to forming the n-type gate structure on the second plurality of nanostructure channel layers.

In a sixth implementation, alone or in combination with one or more of the first through fifth implementations, the self-assembled monolayer film includes a material that promotes adsorption of the self-assembled monolayer film to the gate dielectric layer, and that inhibits adsorption of precursors of the p-type metal layer on the gate dielectric layer.

In a seventh implementation, alone or in combination with one or more of the first through sixth implementations, forming the self-assembled monolayer film on the gate dielectric layer that is around the second plurality of nanostructure channel layers includes forming the self-assembled monolayer film on the gate dielectric layer that is around the second plurality of nanostructure channel layers, and that is around the first plurality of nanostructure channel layers, forming a masking layer (e.g., a masking layer 1410) over the second plurality of nanostructure channel layers, and removing the self-assembled monolayer film from the first plurality of nanostructure channel layers while the masking layer prevents the self-assembled monolayer film from being removed from the second plurality of nanostructure channel layers.

Although FIG. 15 shows example blocks of process 1500, in some implementations, process 1500 includes additional blocks, fewer blocks, different blocks, or differently arranged blocks than those depicted in FIG. 15. Additionally, or alternatively, two or more of the blocks of process 1500 may be performed in parallel.

In this way, the techniques described herein include forming respective (different) types of gate metals for a PMOS nanostructure transistor and keeping an intrinsic NMOS nanostructure transistor of the semiconductor device. A p-type gate metal may be formed around nanostructure channels for the PMOS nanostructure transistor. A self-assembled monolayer may then be formed on the surface of the p-type gate metal layer. During formation of an n-type gate metal around the nanostructure channels for the NMOS nanostructure transistor, the self-assembled monolayer on the p-type gate metal resists formation of the n-type gate metal on the p-type gate metal. This results in little-to-no n-type gate metal deposition on the p-type gate metal, which minimizes the p-type threshold voltage (PVₜ) impact to the PMOS nanostructure transistor. In this way, the techniques described herein enable the work functions of the NMOS nanostructure transistor and the PMOS nanostructure transistor to both be tuned for achieving desirable threshold voltages for the NMOS nanostructure transistor and the PMOS nanostructure transistor. This enables low current leakages to be achieved for the NMOS nanostructure transistor and the PMOS nanostructure transistor, and enables a high operating efficiency to be achieved for the NMOS nanostructure transistor and the PMOS nanostructure transistor.

As described in greater detail above, some implementations described herein provide a method. The method includes forming a first plurality of nanostructure channel layers that are arranged in a direction that is approximately perpendicular to a semiconductor substrate of a semiconductor device. The method includes forming a second plurality of nanostructure channel layers that are arranged in the direction that is approximately perpendicular to the semiconductor substrate. The method includes forming a first type metal layer wrapping around each of the first plurality of nanostructure channel layers. The method includes forming a self-assembled monolayer film on the first type metal layer. The method includes forming a second type metal layer on the second plurality of nanostructure channel layers, where the self-assembled monolayer film inhibits formation of the second type metal layer on the first type metal layer.

As described in greater detail above, some implementations described herein provide a method. The method includes forming a first plurality of nanostructure channel layers that are arranged in a direction that is approximately perpendicular to a semiconductor substrate of a semiconductor device. The method includes forming a second plurality of nanostructure channel layers that are arranged in the direction that is approximately perpendicular to the semiconductor substrate. The method includes forming a p-type metal layer of a first gate structure on the first plurality of nanostructure channel layers. The method includes depositing a solution onto the p-type metal layer, where the solution comprises a material that is dissolved in a solvent. The method includes curing the solution to form, on the p-type metal layer, a self-assembled monolayer film containing the material. The method includes forming an n-type metal layer of a second gate structure on the second plurality of nanostructure channel layers, where the material of the self-assembled monolayer film comprises a side chain group that inhibits adsorption of the n-type metal layer on the p-type metal layer.

As described in greater detail above, some implementations described herein provide a method. The method includes forming a first plurality of nanostructure channel layers that are arranged in a direction that is approximately perpendicular to a semiconductor substrate of a semiconductor device. The method includes forming a second plurality of nanostructure channel layers that are arranged in the direction that is approximately perpendicular to the semiconductor substrate. The method includes forming a gate dielectric layer around the first plurality of nanostructure channel layers and around the second plurality of nanostructure channel layers. The method includes forming a self-assembled monolayer film on the gate dielectric layer that is around the second plurality of nanostructure channel layers. The method includes forming a p-type metal layer of a first gate structure on the first plurality of nanostructure channel layers, where the material of the self-assembled monolayer film inhibits adsorption of the p-type metal layer on the gate dielectric layer that is around the second plurality of nanostructure channel layers. The method includes an n-type metal layer of a second gate structure on the second plurality of nanostructure channel layers after forming the p-type metal layer.

As described in greater detail above, some implementations described herein provide a semiconductor device. The semiconductor device includes a first plurality of nanostructure channel layers arranged in a direction that is approximately perpendicular to a semiconductor substrate of the semiconductor device. The semiconductor device includes a second plurality of nanostructure channel layers, adjacent to the first plurality of nanostructure channel layers, that are arranged in the direction that is approximately perpendicular to the semiconductor substrate. The semiconductor device includes a first gate structure, wrapping around the first plurality of nanostructure channel layers, comprising, a p-type metal layer a residue, on the p-type metal layer, that contains ligands of at least one of: sulfur (S), silicon (SI), or phosphorus (P). The semiconductor device includes a second gate structure, wrapping around each of the second plurality of nanostructure channel layers, comprising an n-type metal layer.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first plurality of nanostructure channel layers that are arranged in a direction that is approximately perpendicular to a semiconductor substrate of a semiconductor device;
forming a second plurality of nanostructure channel layers that are arranged in the direction that is approximately perpendicular to the semiconductor substrate;
forming a first type metal layer wrapping around each of the first plurality of nanostructure channel layers;
forming a self-assembled monolayer film on the first type metal layer; and
forming a second type metal layer on the second plurality of nanostructure channel layers,
wherein the self-assembled monolayer film inhibits formation of the second type metal layer on the first type metal layer.

2. The method of claim 1, wherein forming the self-assembled monolayer film comprises:
depositing, by spin coating, a solution that contains material of the self-assembled monolayer film; and
performing a spin dry operation to cure the solution to form the self-assembled monolayer film.

3. The method of claim 1, further comprising:
removing the self-assembled monolayer film after forming the second type metal layer.

4. The method of claim 3, wherein a residue from the self-assembled monolayer film remains on the first type metal layer after removal of the self-assembled monolayer film.

5. The method of claim 3, wherein removing the self-assembled monolayer film comprises:
performing a thermal decomposition operation on the self-assembled monolayer film to decompose hydrocarbon chains of the self-assembled monolayer film.

6. The method of claim 5, wherein performing the thermal decomposition operation comprises:
heating the self-assembled monolayer film to a temperature that is included in a range of approximately 300 degrees Celsius to approximately 500 degrees Celsius.

7. The method of claim 3, wherein removing the self-assembled monolayer film comprises:
performing a plasma treatment operation on the self-assembled monolayer film to remove the self-assembled monolayer film.

8. The method of claim 1, wherein forming the self-assembled monolayer film comprises:
forming the self-assembled monolayer film as a discontinuous thin film.

9. A method, comprising:
forming a first plurality of nanostructure channel layers that are arranged in a direction that is approximately perpendicular to a semiconductor substrate of a semiconductor device;
forming a second plurality of nanostructure channel layers that are arranged in the direction that is approximately perpendicular to the semiconductor substrate;
forming a gate dielectric layer around the first plurality of nanostructure channel layers and around the second plurality of nanostructure channel layers;
forming a self-assembled monolayer film on the gate dielectric layer that is around the second plurality of nanostructure channel layers;
forming a p-type metal layer of a first gate structure on the first plurality of nanostructure channel layers,
wherein the material of the self-assembled monolayer film inhibits adsorption of the p-type metal layer on the gate dielectric layer that is around the second plurality of nanostructure channel layers; and
forming an n-type metal layer of a second gate structure on the second plurality of nanostructure channel layers after forming the p-type metal layer.

10. The method of claim 9, wherein the self-assembled monolayer film is a first self-assembled monolayer film; and
wherein the method further comprises:
depositing a solution onto the p-type metal layer that is on the first plurality of nanostructure channels prior to forming the n-type metal layer,
wherein the solution comprises a material that is dissolved in a solvent;
curing the solution to form, on the p-type metal layer, a second self-assembled monolayer film containing the material, and
wherein the material of the second self-assembled monolayer film comprises a side chain group that inhibits adsorption of the n-type metal layer on the p-type metal layer.

11. The method of claim 10, wherein the material of the second self-assembled monolayer film comprises an anchoring group that promotes adsorption of the material of the second self-assembled monolayer film on the p-type metal layer; and
wherein the anchoring group comprises at least one of:
an amino group,
a thiol group,
a carboxyl group,
a carbonyl group,
a trichlorosilane (SiCl₃), or
a phosphonate.

12. The method of claim 10, further comprising:
removing the second self-assembled monolayer film after forming the n-type metal layer,
wherein a self-assembled monolayer film residue remains on the p-type metal
layer after removal of the second self-assembled monolayer film, and
wherein the self-assembled monolayer film residue comprises at least one of:
a sulfur (S) ligand,
a silicon (Si) ligand, or
a phosphorous (P) ligand.

13. The method of claim 10, wherein the solvent comprises at least one of:
a gamma-butyrolactone (GBL) solvent,
a diethylformamide (DEF) solvent,
a propylene glycol methyl ether acetate (PGMEA) solvent, or
a propylene glycol methyl ether (PGME) solvent.

14. The method of claim 9, further comprising:
removing the self-assembled monolayer film from the gate dielectric layer that is around the second plurality of nanostructure channel layers prior to forming the n-type gate structure on the second plurality of nanostructure channel layers.

15. The method of claim 9, wherein the self-assembled monolayer film comprises a material that promotes adsorption of the self-assembled monolayer film to the gate dielectric layer, and that inhibits adsorption of precursors of the p-type metal layer on the gate dielectric layer.

16. The method of claim 9, wherein forming the self-assembled monolayer film on the gate dielectric layer that is around the second plurality of nanostructure channel layers comprises:
forming the self-assembled monolayer film on the gate dielectric layer that is around the second plurality of nanostructure channel layers, and that is around the first plurality of nanostructure channel layers;
forming a masking layer over the second plurality of nanostructure channel layers; and
removing the self-assembled monolayer film from the first plurality of nanostructure channel layers while the masking layer prevents the self-assembled monolayer film from being removed from the second plurality of nanostructure channel layers.

17. A semiconductor device, comprising:
a first plurality of nanostructure channel layers arranged in a direction that is approximately perpendicular to a semiconductor substrate of the semiconductor device;
a second plurality of nanostructure channel layers, adjacent to the first plurality of nanostructure channel layers, that are arranged in the direction that is approximately perpendicular to the semiconductor substrate;
a first gate structure, wrapping around the first plurality of nanostructure channel layers, comprising:
a p-type metal layer; and
a residue, on the p-type metal layer, that contains ligands of at least one of:
sulfur (S),
silicon (SI), or
phosphorus (P); and
a second gate structure, wrapping around each of the second plurality of nanostructure channel layers, comprising an n-type metal layer.

18. The semiconductor device of claim 17, wherein a concentration of aluminum (Al) in the second gate structure is greater than a concentration of aluminum in the first gate structure.

19. The semiconductor device of claim 17, wherein the residue is a discontinuous thin film on the p-type metal layer.

20. The semiconductor device of claim 17, wherein material of the n-type metal layer is also included on the p-type metal layer; and
wherein a thickness of the material of the n-type metal layer on the p-type metal layer is less than a thickness of the n-type metal layer on the second gate structure.
